(19) United States
(12) Patent Application Publication
(10) Pub. No.: US 2026/0164838 A1
(43) Pub. Date: Jun. 11, 2026

(54) SiC UV PHOTODETECTOR

(71) Applicant: BAE SYSTEMS Information and Electronic Systems Integration Inc., Nashua, NH (US)

(72) Inventors: Amrita V. Masurkar, Burlington, MA (US); Isaac Wildeson, Amherst, NH (US)

(73) Assignee: BAE SYSTEMS Information and Electronic Systems Integration Inc., Nashua, NH (US)

(21) Appl. No.: 18/975,715

(22) Filed: Dec. 10, 2024

(51) Int. Cl. H10F 77/1226; H10F 30/28; H10F 71/00; H10F 77/00; H10F 77/20; H10F 77/40

(52) U.S. Cl. CPC H10F 77/1227; H10F 30/28; H10F 71/121; H10F 71/128; H10F 71/134; H10F 77/206; H10F 77/413; H10F 77/933

(57) ABSTRACT

A photodetector, made from a silicon carbide semiconductor, comprising a photodiode portion and a junction field-effect transistor (JFET) portion, integrated into a single chip, the JFET portion having a lateral architecture enabled through fabrication using only implantation-based doping processes in a manufacturing process where a photodiode and a JFET are manufactured simultaneously using the same manufacturing process.

### FIELD

The present disclosure relates to a photodetector that is compatible with high-temperature use environments.

### BACKGROUND

There are many sensing applications that require harsh environments. In particular, there are high-temperature environments where the sensing device is required to operate without failure or performance issues. One such environment is for combustion engines. Engines used in modern fighter jets employ afterburners as a second combustion stage to produce additional thrust during takeoff, supersonic flight, and special maneuvers. Although the afterburner operates with extremely sensitive tolerances, the temperature of the flame in an afterburner can reach 1650° C., making flame detection and monitoring both critical and challenging. In modern fighter jets, engines typically use Geiger-Muller vacuum tubes (GMVTs) for monitoring and controlling afterburner operation. Reliance on GMVTs, however, has become problematic for several reasons. One is that the GMVTs are fragile and are difficult and costly to manufacture. GMVTs are bulky and heavy, interfering with low size, weight, power, and cost (SWaP-C) objectives. GMVTs are also prone to problems with leakage. GMVTs also operate at several hundred volts, requiring bulky and power-hungry power supplies, again interfering with low size, weight, power, and cost (SWaP-C) objectives. Moreover, manufacturing of GMVTs requires an outdated skill set that is becoming increasingly obscure as technicians skilled in vacuum tube technology are being lost through retirement. Furthermore, GMVTs are inherently discrete components, —rendering device integration with amplification and processing circuitry challenging. GMVTs also cannot distinguish photon energies; if spectral resolution is required of the detector, GMVTs cannot satisfy this requirement. Moreover, GMVTs are bulky, so cannot be used in arrays to provide spatially resolved information.

What is needed, therefore, is a UV photodetector of a structure that is able to withstand high-temperature use environments and is robust to vibrations, and the like, that can be manufactured easily and relatively inexpensively using modern semiconductor manufacturing processes, that can be operated with lower voltages at lower power, that is small and light to support SWaP-C objectives, that can be integrated with other on-chip electronic circuitry, and that can provide spectral information and/or spatially resolved information when needed.

### SUMMARY

The present disclosure is an integrated photodetector, and manufacturing method thereof, that provides a solid-state alternative to the GMVT, where the solid-state semiconductor structure of the silicon carbide (SiC) photodetector can be manufactured far more easily and potentially less expensively than a GMVT, while also enabling a transimpedance amplifier to be co-located on the same chip as the photodiode detector, reducing parts counts and system complexity, and enhancing reliability. Unlike bulky GMVTs, the monolithically integrated solid-state semiconductor structure is robust to mechanical shock and vibration as well, and elimination of the external leads between the GMVT and the transimpedance amplifier reduces substantially the possibility of interconnection failure and prevents loss of signal integrity between the photodiode detector and the transimpedance amplifier. Manufacturability of the integrated SiC photodetector is further enhanced through a novel combination of lateral device architecture and heavy use of ion implantation, reducing sensitivity to process variation when compared to SiC photodetectors that use vertical structures that rely on growth and etching of epitaxial layers. As SiC photodetectors are transparent to IR and visible wavelengths, there is no need for complex optical filters that would be required when using other semiconductor technologies, further simplifying the system structure. Additionally, the integrated SiC photodetector operates at about 10 V, an order of magnitude less than GMVTs, greatly simplifying power supply issues. The SiC photodetector, with the structure alluded to above and set forth in detail below, enables operation at temperatures up to 800° C. or more, enabling use in monitoring and controlling not only afterburners in engines of fighter jets, but also in monitoring and controlling flames in power generation, petrochemical refining, chemical processing, blast furnaces, waste incineration, rocket propulsion systems, and the like, in environments beyond the withstand temperatures of GMVTs. Another benefit of the disclosed solution is that use of semiconductor technology facilitates miniaturization, and therefore enables multi-pixel arrays for spatially resolved and/or chromatically resolved data within a low SWAP-C design.

One embodiment provides a photodetector, comprising: at least one photodetector structure, disposed on a substrate, said photodetector structure comprising: an unintentionally-doped silicon carbide high-resistivity epitaxial layer disposed over the substrate; at least one heavily-doped n-type cathode region formed in the high-resistivity epitaxial layer; at least one heavily-doped p-type anode region formed in the high-resistivity epitaxial layer; at least one photosensitive region, of the high-resistivity epitaxial layer, interposed between the anode region and the cathode region in the high-resistivity epitaxial layer; an insulating layer formed over at least a portion of the substrate, with windows to allow access to the cathode region and to the anode region, and configured to enable UV radiation to be incident onto the photosensitive region; and silicide contacts in contact with the cathode region and the anode region; wherein the anode region, the cathode region, and the photosensitive region are formed in the high-resistivity epitaxial layer in a lateral configuration.

Another embodiment provides such a photodetector, wherein the substrate is a SiC epi-compatible material.

A further embodiment provides such a photodetector wherein the substrate is a SiC 4H or 6H substrate of one conductivity type having an opposite-conductivity-type low-resistivity epitaxial layer formed on a surface thereof.

Yet another embodiment provides such a photodetector, wherein the substrate is an insulating substrate having a SiO2 layer on a surface thereof.

A yet further embodiment provides such a photodetector, wherein: the substrate is an insulating substrate having a metal layer on a surface thereof; and metal vias pass through the high-resistivity epitaxial layer and connect with the metal layer.

Still another embodiment provides such a photodetector, further comprising at least one optical filter, provided over at least one said photosensitive region.

A still further embodiment provides such a photodetector, further comprising at least one first junction field-effect transistor, comprising: a lightly-doped first channel region, of a first conductivity type, formed in the high-resistivity epitaxial layer; a heavily-doped first gate region, of a second conductivity type that is the opposite conductivity type from the first conductivity type, formed at least partially in the channel region; and heavily-doped first source/drain regions, of the first conductivity type, formed at least partially in the channel region, wherein: the insulating layer has windows opened to allow access also to the first gate region and the first source/drain regions; and silicide contacts contact also the first gate region and the first source/drain regions.

Even another embodiment provides such a photodetector, wherein; the first source/drain regions comprise at least one first source/drain subregion and at least one second source/drain subregion, arranged opposing each other; and the first gate region comprises a plurality of first gate regions, arranged in a row between the first source/drain subregion and the second source/drain subregion.

An even further embodiment provides such a photodetector, wherein: the first source/drain subregion comprises a plurality of first source/drain subregions, arranged in a row parallel to a row of the first gate regions, such that each of the first source/drain subregions faces an aforementioned second source/drain subregion through a space between mutually adjacent first gate regions.

A still even another embodiment provides such a photodetector, wherein: the first gate region comprises a plurality of first gate regions, arranged in two rows, with each individual first gate region in one row paired with and facing a corresponding first gate region in the other row; and the first source/drain regions are arranged in a row, parallel to the rows of first gate regions, facing each other through spaces between pairs of first gate regions.

A still even further embodiment provides such a photodetector, further comprising a lightly-doped well, of the second conductivity type, containing the first channel region, the first gate region, and the first source/drain regions.

Still yet another embodiment provides such a photodetector, further comprising an amplifier, comprising a plurality of the junction field-effect transistor, electrically coupled to the p-type anode region and the n-type cathode region through a patterned metal interconnection layer.

A still yet further embodiment provides such a photodetector, further comprising at least one second junction field-effect transistor, comprising: a lightly-doped second channel region, of the second conductivity type, formed in the high-resistivity epitaxial layer; a heavily-doped second gate region, of the first conductivity type, formed at least partially in the channel region of the second conductivity type; and heavily-doped second source/drain regions, of the second conductivity type, formed at least partially in the channel region of the second conductivity type.

Even yet another embodiment provides such a photodetector, wherein: the at least one photodetector structure comprises a plurality of photodetector structures; and the at least one first junction field-effect transistor comprises a plurality of first junction field-effect transistors, wherein a plurality of pixel photodetector structures is arranged in a matrix, where each of the plurality of pixel photodetector structures comprises at least one of said photodetector structures and at least one of said first junction field-effect transistors.

An even yet further embodiment provides such a photodetector, wherein: the at least one photodetector structure comprises a plurality of photodetector structures, arranged in a matrix; and at least one cathode or at least one anode is connected to the metal layer through at least one of the metal vias.

Still even yet another embodiment provides a method for manufacturing a photodetector, comprising: growing a high-resistivity epitaxial layer over a substrate of a SiC epi-compatible material; forming an anode-forming hard mask layer over the high-resistivity epitaxial layer and patterning the anode-forming hard mask layer to form a window over an area for heavy ion implantation of a p-type dopant for forming an anode of a photodiode; performing heavy heated ion implantation of the p-type dopant and removing the anode-forming hard mask layer; forming a cathode-forming hard mask layer over the high-resistivity epitaxial layer and patterning the cathode-forming hard mask layer to form a window over an area for heavy ion implantation of an n-type dopant for forming a cathode of the photodiode; performing heavy heated ion implantation of the n-type dopant; and removing the cathode-forming hard mask layer; cleaning the surface of the substrate; depositing an anneal cap of a thermally stable material to prevent step-bunching, annealing the anneal cap, and removing the anneal cap; and forming a contact-forming hard mask layer over the high-resistivity epitaxial layer, patterning the contact-forming hard mask layer to form a window over a contact-forming area of a region into which ions have been implanted, depositing a film of a metal for forming an ohmic contact layer, annealing, silicidizing the ohmic contact layer, and removing any residual unreacted metal.

A still even yet further embodiment provides such a method, further comprising forming a p channel for a junction field-effect transistor, comprising: forming a p channel-forming hard mask layer over the high-resistivity epitaxial layer; patterning the p channel-forming hard mask layer to form windows over areas for light ion implantation of a p-type dopant; performing light heated ion implantation of the p-type dopant, and removing the p channel-forming hard mask layer; and forming an n channel for a junction field-effect transistor, comprising: forming a n channel-forming hard mask layer over the high-resistivity epitaxial layer; patterning the n channel-forming hard mask layer to form windows over areas for light ion implantation of the n-type dopant; performing light heated ion implantation of the n-type dopant; and removing the n channel-forming hard mask layer; wherein patterning the anode-forming hard mask layer comprises forming windows also over areas for forming a p+ gate of an n-type junction field-effect transistor and a p+ source and a p+ drain of a p-type junction field-effect transistor, in addition to the window for forming the anode of the photodiode; and patterning the cathode-forming hard mask layer comprises forming windows over areas for forming an n+ gate of the p-type junction field-effect transistor and an n+ source and an n+ drain of the n-type junction field-effect transistor, in addition to forming the cathode of the photodiode.

Yet still even another embodiment provides such a method, further comprising: growing, over the substrate, a low-resistivity silicon carbide epitaxial layer of the conductivity type that is opposite of the conductivity type of the substrate, prior to growing the high-resistivity epitaxial layer.

A yet still even further embodiment provides such a method, further comprising forming an optical filter.

A yet still even further still embodiment provides such a method, further comprising: bonding a high-resistivity epitaxial layer to a carrier substrate through a photoresist layer; removing the substrate of the SiC epi-compatible material; after removing the substrate of the SiC epi-compatible material, depositing a SiO2 layer onto the high-resistivity epitaxial layer; bonding the SiO2 layer onto an insulating substrate; and removing the carrier substrate.

Another further embodiment provides such a method, further comprising: bonding the high-resistivity epitaxial layer to a carrier substrate through a photoresist layer; removing the substrate of the SiC epi-compatible material; forming vias through the high-resistivity epitaxial layer; metalizing the vias and forming a metal layer on the epitaxial layer; and bonding the metal layer onto a metal layer that is on an insulating substrate.

The features and advantages described herein are not all-inclusive and, in particular, many additional features and advantages will be apparent to one of ordinary skill in the art in view of the drawings, specification, and claims. Moreover, it should be noted that the language used in the specification has been selected principally for readability and instructional purposes, and not to limit the scope of the inventive subject matter.

### BRIEF DESCRIPTION OF THE DRAWINGS

FIG. 1 is a schematic diagram showing portions of a silicon carbide photodetector according to an embodiment.

FIG. 2 is a schematic cross-sectional diagram showing an embodiment of a photodiode portion in a photodetector.

FIG. 3 is a schematic plan view diagram showing an embodiment of a photodiode portion in a photodetector, without the patterned metal interconnection layer.

FIG. 4 is a schematic plan view diagram showing an embodiment of a photodiode portion in a photodetector, with the patterned metal interconnection layer.

FIG. 5 is a schematic plan view diagram showing an embodiment of n- and p-type junction field-effect transistors, without the patterned metal interconnection layer.

FIG. 6 is a schematic plan view diagram showing another embodiment of n- and p-type junction field-effect transistors, without the patterned metal interconnection layer, configured with multiple channels to increase current.

FIG. 7 is a schematic plan view diagram showing yet another embodiment of n- and p-type junction field-effect transistors, without the patterned metal interconnection layer, configured with multiple channels to increase current and configured with discontinuous sources and drains to reduce parasitic capacitance.

FIG. 8 is a schematic plan view diagram showing yet even another embodiment of n- and p-type junction field-effect transistors, without the patterned metal interconnection layer, configured with multiple channels to increase current.

FIG. 9 is a schematic cross-sectional diagram showing an embodiment of a multifrequency photodetector array according to an embodiment.

FIG. 10 is a schematic diagram showing a photodetector array in a photodetector according to an embodiment.

FIG. 11 is a schematic diagram showing a photodetector array in a photodetector according to another embodiment.

FIG. 12 is a schematic diagram showing details of a structure for a photodetector array, and electrical connections therein, according to an embodiment.

FIG. 13 is a schematic diagram showing a detailed structure of a segmented anode region in a pixel structure in a photodetector array.

FIG. 14 is a schematic diagram showing details of a structure for a photodetector array, and electrical connections therein, according to another embodiment.

FIG. 15 is a schematic diagram showing details of a structure for a photodetector array, and electrical connections therein, according to another embodiment.

FIG. 16A through FIG. 16I show manufacturing step diagrams for explaining a method for manufacturing a photodetector according to an embodiment.

FIG. 17 shows a manufacturing step diagram for explaining a method for manufacturing a color filter on a photodetector according to an embodiment.

FIG. 18 shows a manufacturing step diagram for explaining a method for manufacturing an epitaxial layer on an insulating substrate. according to an embodiment.

FIG. 19 shows a manufacturing step diagram for explaining a method for manufacturing an epitaxial layer with via holes to a conductive ground plane on an insulating substrate. according to an embodiment.

FIG. 20 is a schematic diagram of a UV camera according to an embodiment.

### DETAILED DESCRIPTION

The present disclosure relates to a photodetector, and to a method for manufacturing the same, not only providing a replacement for conventional GMVTs, but enabling easy and inexpensive manufacturing of an ultraviolet photodetector that is able to withstand high temperatures and mechanical shock and vibrations, that provides the benefits of a solid-state structure, and that also provides superior manufacturing repeatability through the use of a lateral architecture.

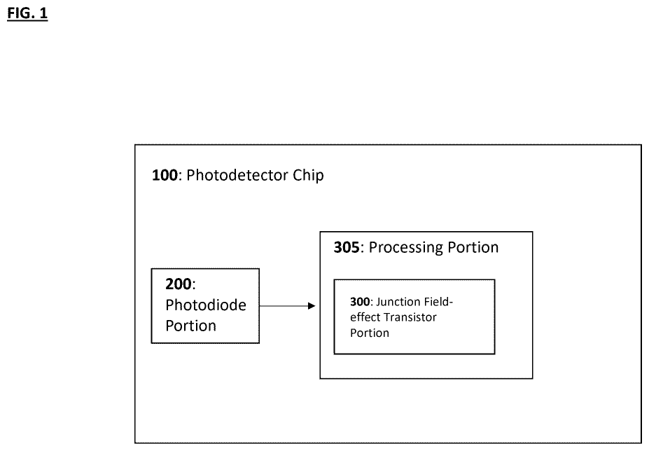

The photodetector will be explained in detail below, citing various embodiments. FIG. 1 is a schematic diagram showing portions of a photodetector according to an embodiment. As depicted in FIG. 1, a photodetector 100 of an embodiment comprises two portions, a photodiode portion 200 and a processing portion 305, for, for example, amplifying the output of the photodiode portion 200 prior to outputting to an external device. The processing portion 305 may comprise a junction field-effect transistor (JFET) portion 300. As will be described below, in embodiments the JFET portion 300 is configured to amplify the signal produced by the photodiode portion 200, doing so using a transimpedance amplifier, not shown, structured from circuit components fabricated as described below. However, it should be noted that embodiments are not limited to those that include the processing portion 305. In embodiments, the photodetector 100 may be limited to only the photodiode portion 200 (i.e, the JFET portion 300 may be omitted), and may instead be coupled electrically to, for example, an external transimpedance amplifier, which may be packaged together with the photodetector 100 on the same circuit board or in a multichip module or may be provided on a separate board. In other embodiments, a transimpedance amplifier may be provided as the processing portion 305 on the same chip as the photodiode portion 200, and may be configured comprising a plurality of junction field-effect transistor portions 300 according to embodiments such as set forth below. As set forth below, in embodiments the photodetector 100, and the photodiode portion 200 and junction field-effect transistor portion 300 thereof, are structured at least partially from silicon carbide, built on a silicon carbide wafer, enabling use in harsh environments, such as in high-temperature environments, where conventional silicon or gallium arsenide semiconductor devices do not generally operate properly. The novel combination of the photodiode portion 200 and the processing portion 305 in a single chip, as depicted in FIG. 1, enables, for example, amplification of the output of the photodiode portion 200 without the signal degradation that would occur if the output were routed to an external device disposed far enough away to be in a more hospitable environment.

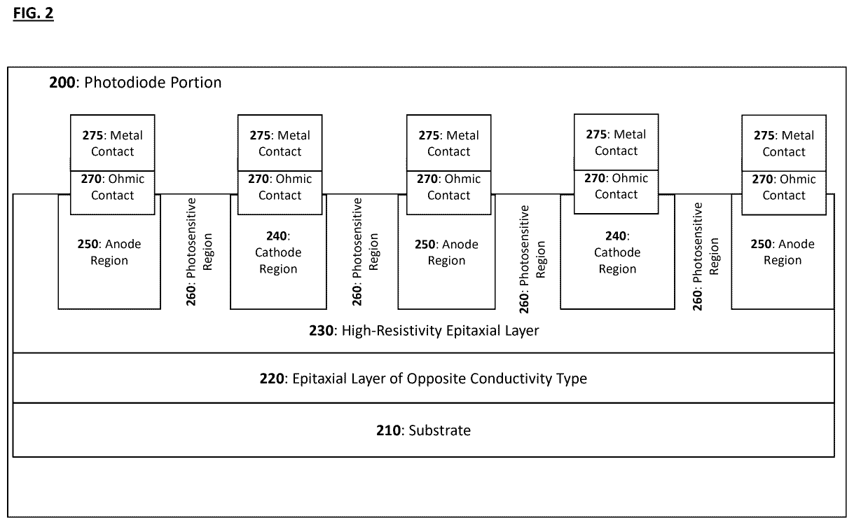

Embodiments of the photodiode portion 200 will be described below in reference to FIG. 2 through FIG. 4. As depicted in these figures, and explained in greater detail below, in embodiments the photodiode portion 200 comprises: a substrate 210; a high-resistivity epitaxial layer (unintentionally-doped silicon carbide epitaxial layer) 230; a plurality of anode regions (heavily-doped p-type anode regions) 240 and a plurality of cathode regions (heavily-doped n-type cathode regions) 250, with photosensitive regions (photosensitive regions of unintentionally-doped silicon carbide) 260 interposed therebetween; ohmic contacts 270 (which, in embodiments, may be metal silicide contacts) that are each in electrical connection with a cathode region 240 or an anode region 250; metal contacts 275 that are in electrical connection with respective ohmic contacts 270; and a patterned metal interconnection layer 280 that connects to the anode regions 250 and cathode regions 240, to serve as a current collector. Note that here the anode regions 240, the photosensitive regions 260, and the cathode regions 250 are disposed in a lateral configuration, that is, in a configuration where these regions do not overlap each other when viewed from above (from the direction that is normal to the surface of the high-resistivity epitaxial layer 230), and where these regions all extend to the surface of the high-resistivity epitaxial layer 230.

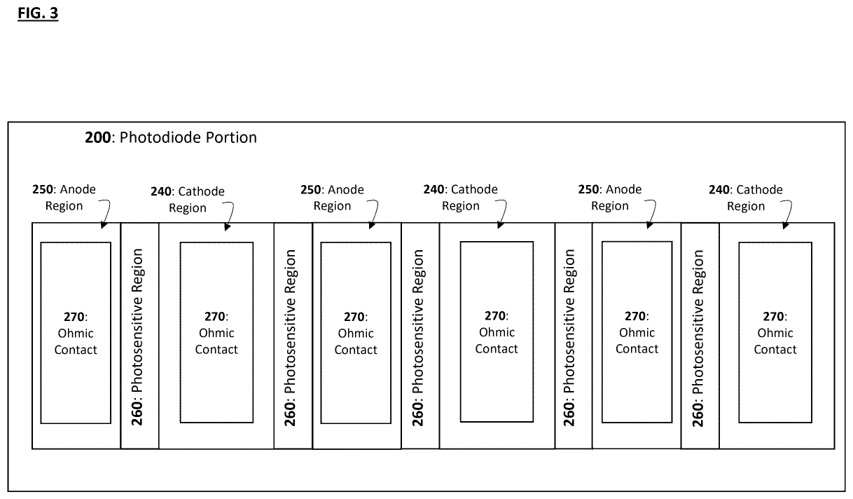

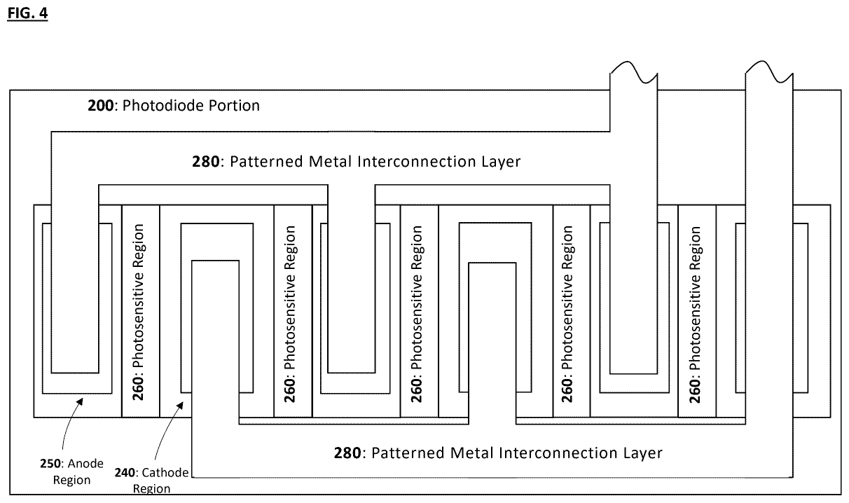

FIG. 2 is a schematic cross-sectional diagram showing an embodiment of a photodiode portion in a photodetector; FIG. 3 is a schematic plan view diagram showing an embodiment of a photodiode portion in a photodetector, without the patterned metal interconnection layer and FIG. 4 is a schematic plan view diagram showing an embodiment of a photodiode portion in a photodetector, with the patterned metal interconnection layer. As depicted in FIG. 2, the photodiode portion 200 of the photodetector 100 of embodiments is built on a substrate 210. In embodiments, the substrate 210 is a silicon carbide substrate, with this material selected due to its superior ability to maintain its functional properties, such as low intrinsic carrier concentration, even at elevated temperatures. It should be emphasized, however, that application of the structures and manufacturing methods set forth below are not limited to only structures built on a silicon carbide substrate. In embodiments, the substrate 210 is a 4H or 6H silicon carbide wafer, which, in embodiments, is an n-type 4H or 6H semi-insulating (SI) silicon carbide wafer. The selection of the n-type 4H or 6H SI silicon carbide wafer as the substrate 210 is due to the ready availability of such a wafer relatively inexpensively, making it possible to take advantage of the fact that embodiments of the manufacturing methods set forth below are compatible with the commercially available, relatively inexpensive, n-type 4H or 6H SI silicon carbide wafers; however, in embodiments the substrate 210 may be of any SiC epi-compatible material.

A high-resistivity epitaxial layer 230 is provided over the substrate 210. There is no quantitative limitation to the definition of “high-resistivity” in this context, except that here “high-resistivity” is to be taken to mean that the epitaxial layer is an unintentionally-doped epitaxial layer. Although ideally this high-resistivity epitaxial layer would be an intrinsic semiconductor layer, in practice some degree of contamination and autodoping during the manufacturing process is unavoidable, and thus “high-resistivity,” as used herein, means only that the semiconductor material is free from intentional doping. The high-resistivity epitaxial layer 230 need not necessarily be in direct contact with the substrate 210. In embodiments, an epitaxial layer 220 (a low-resistivity epitaxial layer, defined as being one that has been intentionally doped) may be provided so as to form a p-n junction with the substrate 210, through the conductivity type of the epitaxial layer 220 being opposite of the conductivity type of the substrate 210. For example, if, in embodiments, the substrate 210 is a commercially available n-type 4H silicon carbide wafer, the low-resistivity epitaxial layer 220 would be a p-type epitaxial layer, with the high-resistivity epitaxial layer 230 provide thereon. In embodiments, any polytype of SiC may be used.

As depicted in FIG. 2 and FIG. 3, the active region of the photodiode portion 200 comprises alternating cathode regions 240 and anode regions 250, with photosensitive regions 260 interposed therebetween. The cathode regions 240 are of an n-type material, which in embodiments may be a high-resistivity (unintentionally-doped) silicon carbide that is then doped with an n-type dopant, which in embodiments may be phosphorus or nitrogen. As will be described in an embodiment of a manufacturing method below, this may be achieved through doping of the high-resistivity epitaxial layer 230 through an ion implantation process. The anode regions 250 are of a p-type material, which in embodiments may be a high-resistivity (unintentionally-doped) silicon carbide that is then doped with a p-type dopant, which in embodiments may be aluminum. As will be described in an embodiment of a manufacturing method below, this may be achieved through doping of the high-resistivity epitaxial layer 230 through an ion implantation process.

The high-resistivity regions that are interposed between the anode regions 250 and the cathode regions 240 act as photosensitive regions 260. P-I-N junctions are formed between the n-type cathode regions 240 and the p-type anode regions 250, creating P-I-N diodes that substantially prevent electric current from flowing in reverse-bias operation until incident photons generate a photocurrent. Electron-hole pair production through UV photons impinging the unintentionally-doped photosensitive regions 260 provide charge carriers, enabling a bias voltage to produce current, which can be detected and amplified by a transimpedance amplifier. Note that, as illustrated in FIG. 2 through FIG. 4, in embodiments multiple anode regions 250 and multiple cathode regions 240 are provided in the photodiode portion 200, arranged in parallel to provide a larger signal for detection by external circuitry.

As depicted in FIG. 2 and FIG. 3, in embodiments an ohmic contact 270 is provided to each anode region 250 and each cathode region 240 where, in embodiments, the ohmic contact 270 also provides a barrier metal function, to prevent diffusion of a contact metal into the bulk of the semiconductor element. It should be noted that despite transparent or translucent materials being formed over the photosensitive region 260 in embodiments, as described below, there is no contact formed over the photosensitive region 260; this is to prevent occlusion of incident radiation. In embodiments an ohmic contact 270 is a silicide. In embodiments the silicide for the ohmic contacts 270 may be a metal silicide such as titanium silicide (TiSi₂), tantalum silicide (TaSi₂) or tungsten silicide (WSi₂). These materials provide good adhesion and low contact resistance with silicon carbide and have low resistivity and good thermal stability.

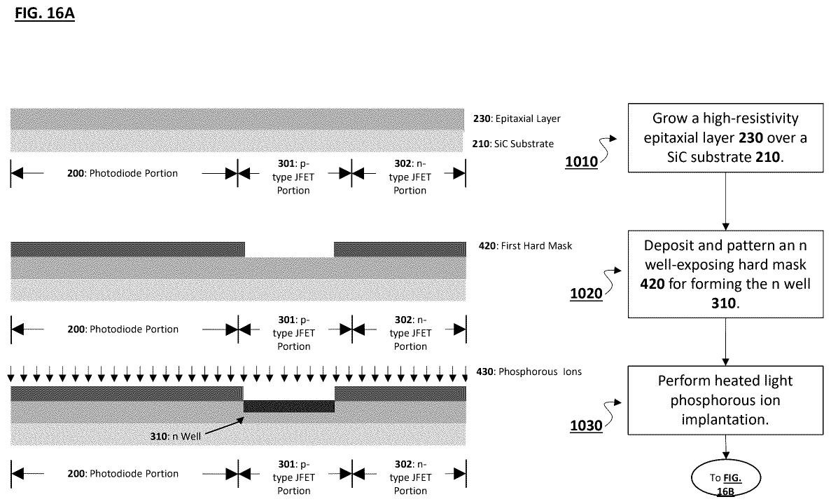

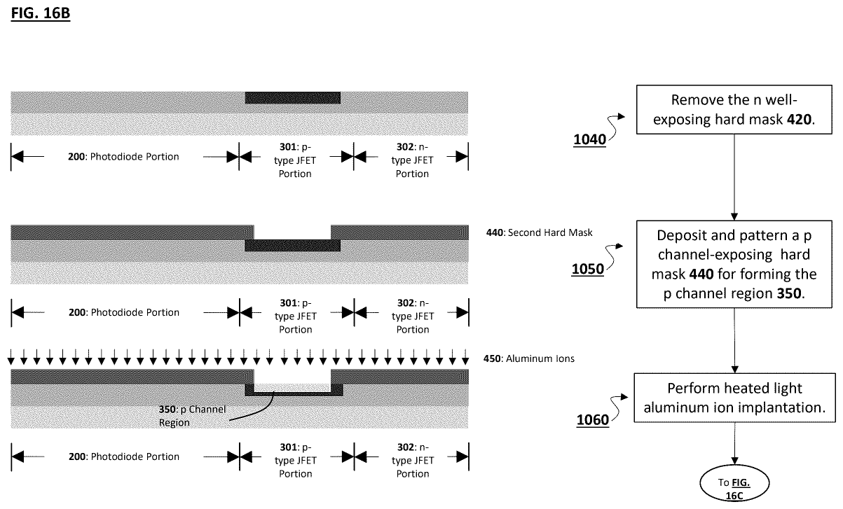

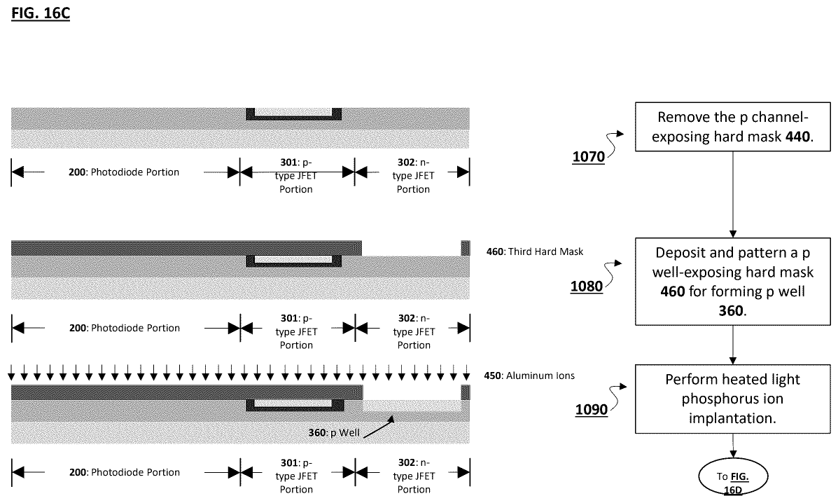

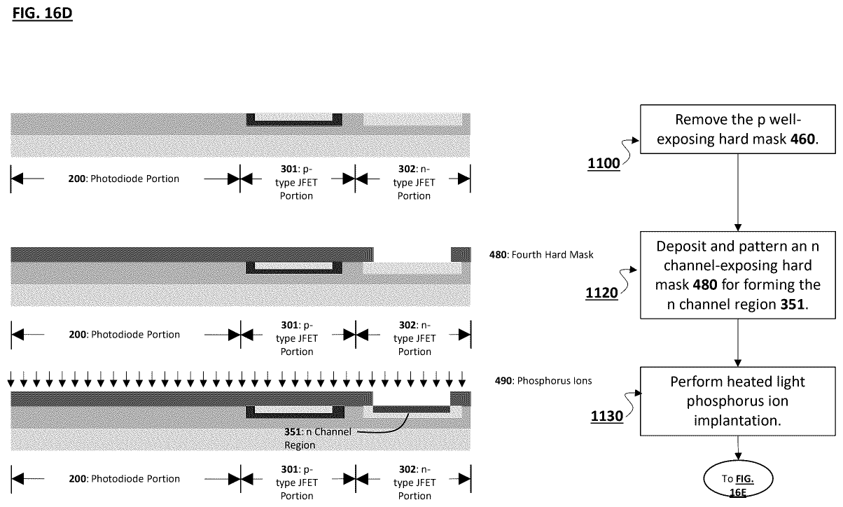

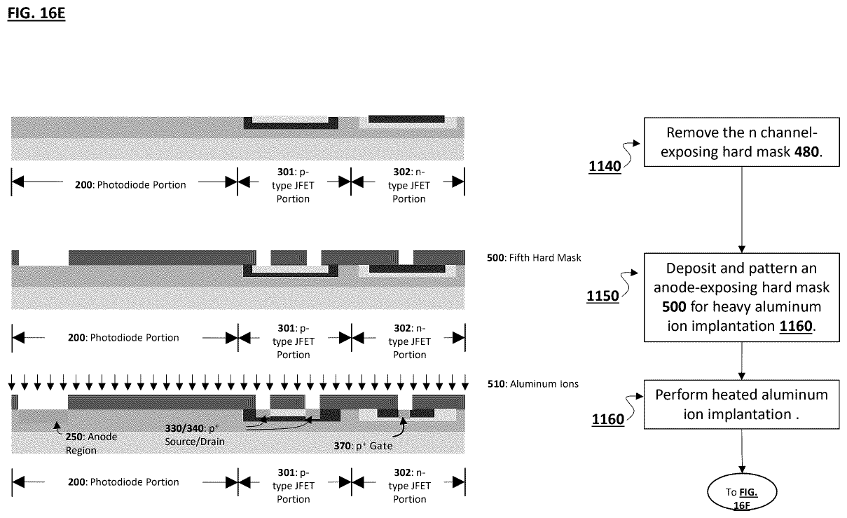

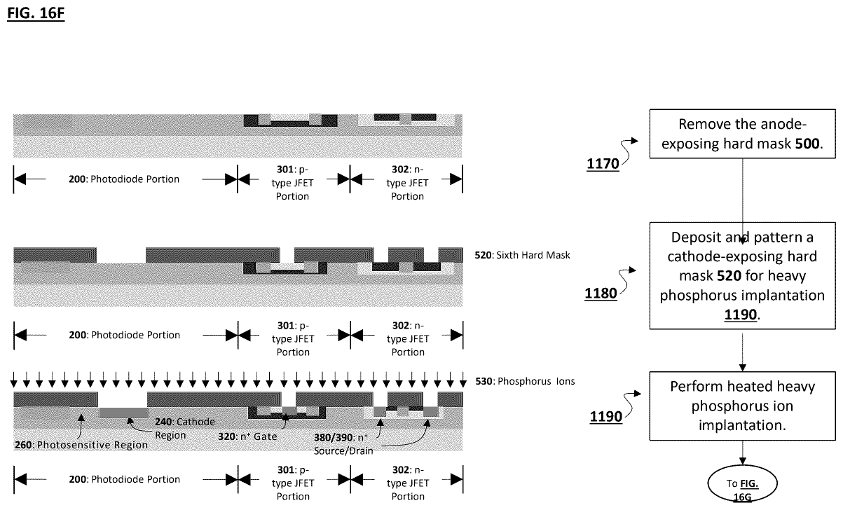

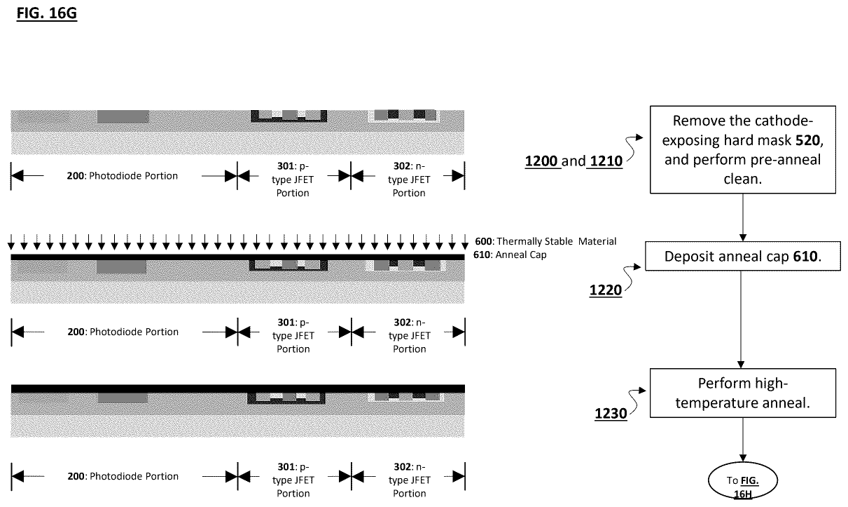

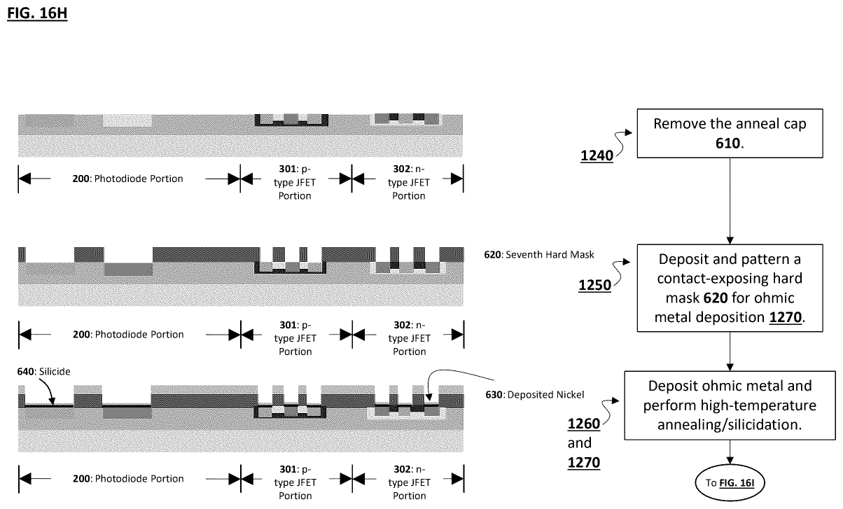

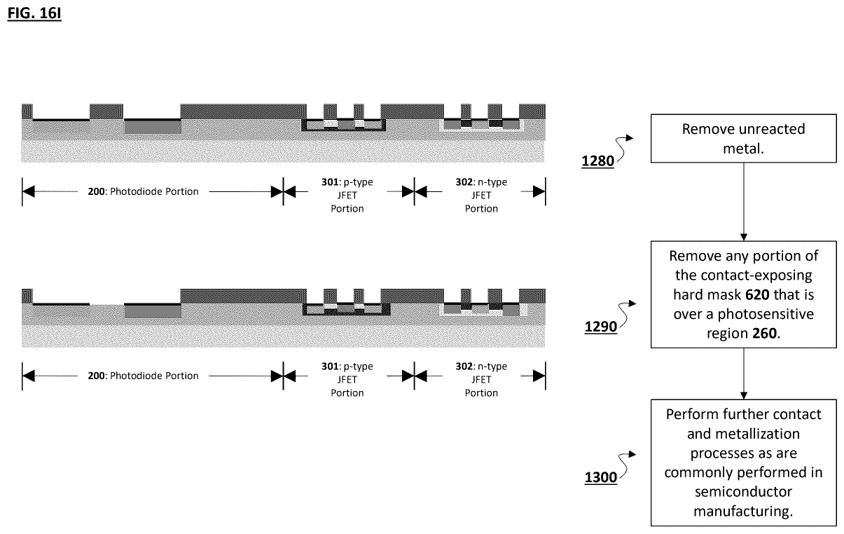

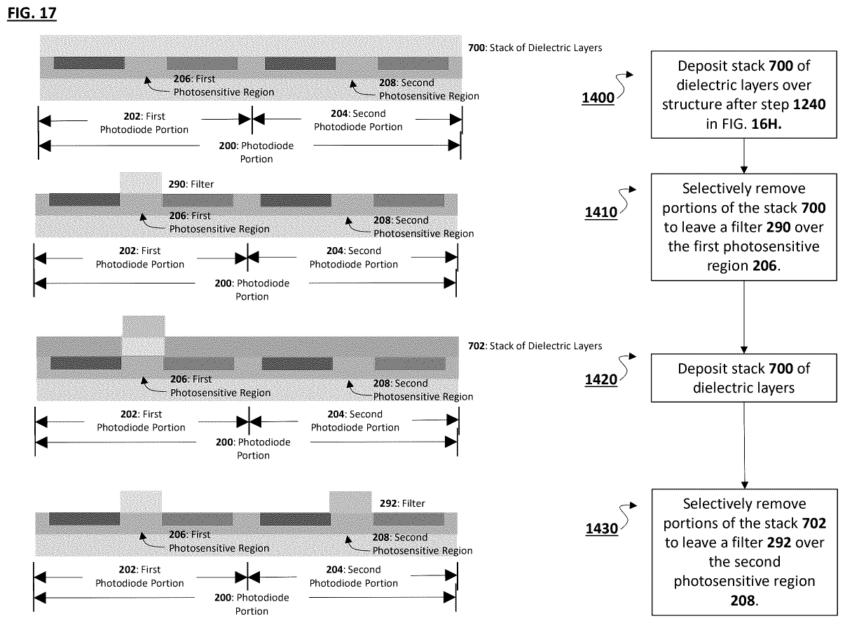

As depicted in FIG. 2, in embodiments a metal contact 275 is provided over each ohmic contact 270, to provide an electrical connection through an insulating layer (such as the contact-forming hard mask 620 that is depicted in FIG. 16) between the ohmic contact 270 and a patterned metal interconnection layer 280, and also to provide functionality as a barrier metal, to prevent migration of the metal of the patterned metal interconnection layer 280, which in embodiments is gold and in other embodiments is platinum, into the silicide. In embodiments, this contact metal, which provides the barrier function, may be TiW. In other embodiments, Ti, Ta, TaN, TiN, or Co may be used as the contact metal. In certain lower temperature applications, Ni or Al may be used instead as the contact metal.

FIG. 4 depicts patterned metal interconnection layers 280 that are used to connect the anode regions 250 of the photodiode portion 200, and the cathode regions 240 of the photodiode portion 200, to elements of a JFET portion 300, described below, or to external circuitry. The configuration of the patterned metal interconnection layers 280 is not limited to that which is illustrated, but rather the configuration may be such that anode regions 250 and cathode regions 240, respectively, are connected in series rather than parallel. Conversely, in embodiments the patterned metal interconnection layers 280 may connect together only subsets of anode regions 250 or connect together subsets of cathode regions 240, particularly in embodiments wherein the photodiode portion 200 is configured as a multifrequency UV sensor or a spatial resolution UV sensor, as described below.

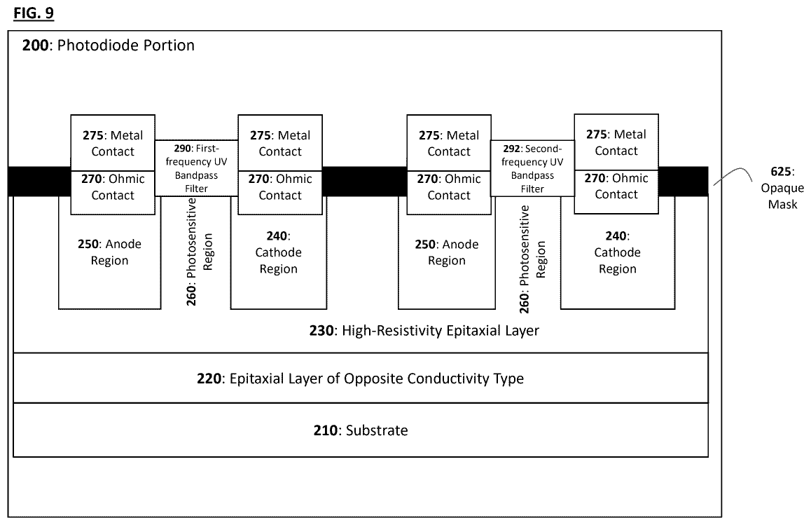

In embodiments, as depicted in FIG. 9, UV bandpass filters (optical filters) 290 and 292 that are tuned to specific frequencies may be provided over subsets of the plurality of photosensitive regions 260, enabling the photosensitive responses of those photosensitive regions 260 to be tuned to specific frequencies of UV radiation. The provision of a plurality of UV bandpass filters 290, having different frequency transmission characteristics, enables detailed monitoring of combustion processes, such as in afterburners in fighter jets, through discriminatory monitoring of the characteristic ultraviolet emission frequencies of CO₂ molecules, H₂O molecules, CO molecules, fuel molecules, hydrocarbon residue molecules, and the like in the combustion byproduct. In such embodiments, the patterned metal interconnection layers 280 are configured to connect together subsets of photosensitive regions 260 that have similar UV bandpass filters 290, to provide a plurality of output signals corresponding to the moieties of molecules in the combustion byproduct. In embodiments a UV bandpass filter 290 is a Fabry-Perot filter consisting of one or more of the following, with no limitation thereto: MgF₂, BaF₂, CaF₂, Al₂O₃, SiO₂, HfO₂, ZnS, ZnO, TiO₂, or the like. Without limitation, these may be deposited onto the surfaces of the applicable photosensitive regions 260 through known deposition and patterning processes, such as physical vapor deposition or chemical vapor deposition (for example, low pressure chemical vapor deposition, atomic layer deposition, sputtering, and the like), followed by photolithography and etching.

In embodiments anti-reflection coatings, not illustrated, are deposited over at least the surfaces of the applicable photosensitive regions 260 to augment the number of photons collected by the detector, where, in embodiments, the anti-reflection coatings may comprise MgF₂, BaF₂, CaF₂, Al₂O₃, SiO₂, HfO2, silicon nitride, TiO₂, and combinations thereof. In embodiments these materials may be applied in the same manner as used for the UV bandpass filter 290, described above. In embodiments an anti-reflection coating 295 can serve also as a UV bandpass filter 290.

In embodiments, the signals produced by the photodiode portion 200 and collected through the patterned metal interconnection layers 280 may be outputted to external devices (not shown) for amplification and analysis. In high-temperature use environments, these external devices may be located away from the photodetector 100, in a cooler location. However, in such a configuration the output signals may undergo degradation prior to arriving at the amplification/analysis equipment. In other embodiments, the output from the photodetector 100 may be received by an external device that is housed in, for example, the same multichip module as the photodetector 100. In yet other embodiments, the amplification circuitry may be in a processing portion 305 that is integrated into the photodetector 100, through the use of the junction field-effect transistor portions 300 alluded to in reference to FIG. 1.

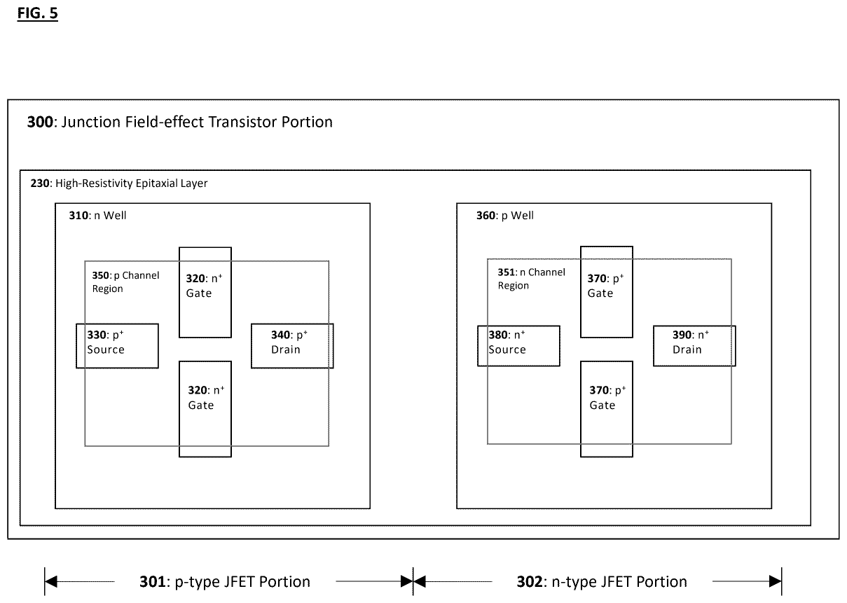

FIG. 5 and FIG. 16A through FIG. 16I depict structures, according to embodiments, for the junction field-effect transistor (JFET) portion 300, FIG. 5 providing a plan view thereof, and FIG. 16 providing cross-sectional views thereof, at different stages in the manufacturing process. In embodiments, the JFET portion 300 consists of p- and n-type lateral JFET portions 301 and 302 (first and second field-effect transistors), where in embodiments the p-type JFET portion 301 has a p+ source 330 (first source/drain region, and first source/drain subregion), a p+ drain 340 (first source/drain region and second source/drain subregion), a dual n+ gate 320 (first gate region) with a portion of a p channel region 350 (first channel region) interposed therebetween, formed in an n well 310, and the n-type JFET portion 302 has an n+ source 380 (second source/drain region), an n+ drain 390 (second source/drain region), and a dual p+ gate 370 (second gate region) with a portion of an n channel region 351 interposed therebetween, formed in a p well 360 (noting that a superscripted “+” symbol in this specification is used to denote “heavily doped,” as defined below). In embodiments, these JFET portions 301 and 302 may be configured to form a complementary JFET, where, in embodiments, complementary JFETs may be employed for, for example, logic functions; however, a JFET portion 301 or 302 of either polarity can be used on its own for, for example, analog functions, such as, for example, in forming a transimpedance amplifier, not shown.

In embodiments, electrical isolation is formed between JFETs and between the photodiode portion 200 and the processing portion 305 through the use of mesa etching or trench isolation, wherein trenches are carved around devices that require isolation. The trenches can then be filled with SiO₂ or another dielectric. In other embodiments, the isolation is through deep field oxidation, consuming the SiC in the epitaxial layer between components. Unlike a vertical JFET structure, all of these transistor elements exist at the surface of the semiconductor chip, and are substantially coplanar, except for the wells 310 and 360 in which the other elements are formed.

The operating principles of a JFET structure are well known in the art, so there is no need to repeat them here. The use of an all-implant lateral structure for the JFET however, enabled through the all-implant manufacturing process described below, provides many benefits over a vertical device structure, such as providing a lower threshold voltage, support for complementary logic, reduced sensitivity to process variation, reduced manufacturing cost, and shorter manufacturing lead time. In embodiments, structuring in silicon carbide enables high-temperature operation, enabling operation at temperatures of 800° C. or more.

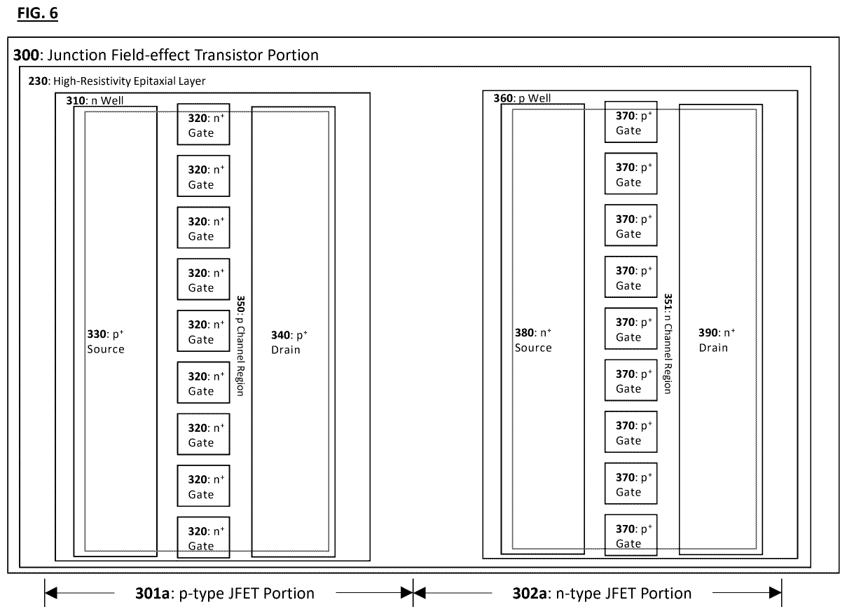

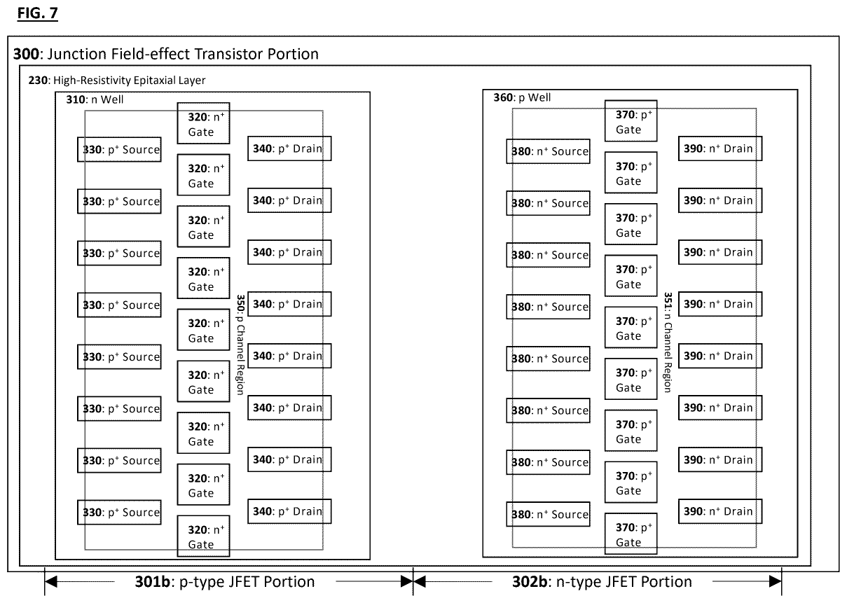

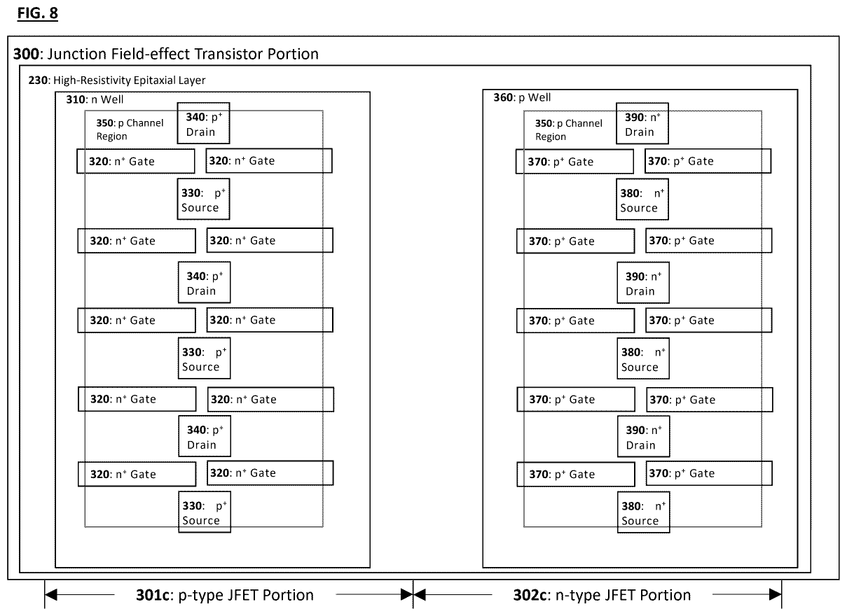

While FIG. 5 shows schematically a plan view of a basic structure of a lateral JFET according to an embodiment, geometries of other embodiment can provide greater current-driving capabilities. In particular, FIG. 6 shows a schematic plan view of an embodiment wherein the sources 330 and 380 and the drains 340 and 390 are elongate, with a plurality of gates 320 and 370, respectively, provided discontinuously therebetween, spaced out in the direction of elongation, thereby providing multiple current channels between the gates 320 or 370, enabling development of a greater current between the sources 330 and 380 and the drains 340 and 390 of the p-type JFET portion 301a and the n-type JFET portion 302a, respectively. FIG. 7 shows a schematic plan view of another embodiment that also provides a plurality of channels, differing from the embodiment in FIG. 6 in that the sources and drains are discontinuous to minimize the area over which sources and drains directly face the gates, to thereby reduce parasitic capacitance between the gates and the associated sources and drains. Such an embodiment increases the electric current while reducing the parasitic capacitance that, in the embodiment depicted in FIG. 5, could hamper the responsiveness of the JFET. FIG. 8 shows a schematic plan view of yet another embodiment of a lateral JFET, in another configuration that provides multiple current channels between sources and drains, to thereby increase the electric current of the JFET.

Given that the JFET portion 300 operates as a standard JFET, and given that passive elements such as resistors and diodes can be structured easily through known manufacturing technologies in silicon carbide, the processing portion 305 can be structured, following standard designs, using a plurality of JFET portions 300 (of the novel lateral architecture that is enabled through the manufacturing method set forth below) together with such passive elements, so no further description of the processing portion 305 is needed. In embodiments, a transimpedance amplifier may be formed from a combination of JFET portions 301 and/or 302 and these passive elements, using standard designs.

In embodiments, photodiode portions 200 are connected, directly or indirectly, to JFET portions 300, enabling the voltages or chargers developed in the photodiode portions 200 to be amplified and subjected to other forms of processing in the processing portion 305. The use of photodiode portions 200 instead of GMVTs for detecting UV radiation, when integrated closely with JFET portions 300 and other components in the processing portion 305, enables a broad variety of devices that are only practical in an integrated circuit.

For example, as depicted in FIG. 9, in embodiments “color filters” (more correctly, optical filters 290 and 292 that pass different frequencies of UV radiation), may be provided over respectively different photosensitive regions 260, and connected through separate traces of metalization layer (not shown) to respective processing circuits in the processing portion 305 to produce a UV sensor able to discern different intensities of different frequencies of UV radiation that is incident on the UV sensor. The chromatic resolution enabled thereby provides richer information than is provided from a UV sensor that cannot discriminate between different frequencies. The first-frequency UV bandpass filter 290 and second-frequency UV bandpass filter 292 of the embodiment depicted in FIG. 9 may be manufactured through the process that will be described below in reference to FIG. 17.

The use of photodiode portions 200 instead of GMVTs for detecting UV radiation, when integrated closely with JFET portions 300 and other components in the processing portion 305, enables, in embodiments, not only enhanced chromatic resolution, but spatial resolution as well. For example, a multipixel array of UV photodiode portions 200 and JFET portions 300 can be used to form a 2D photodetector array 110.

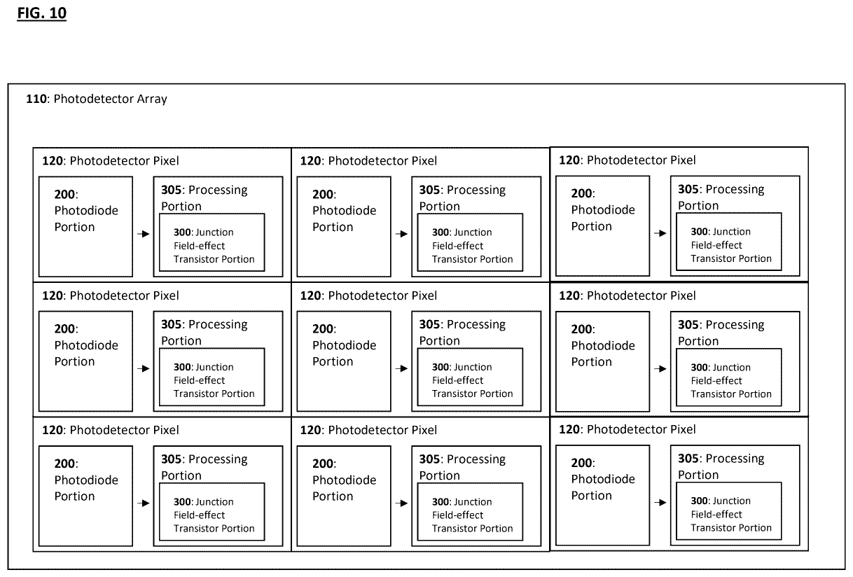

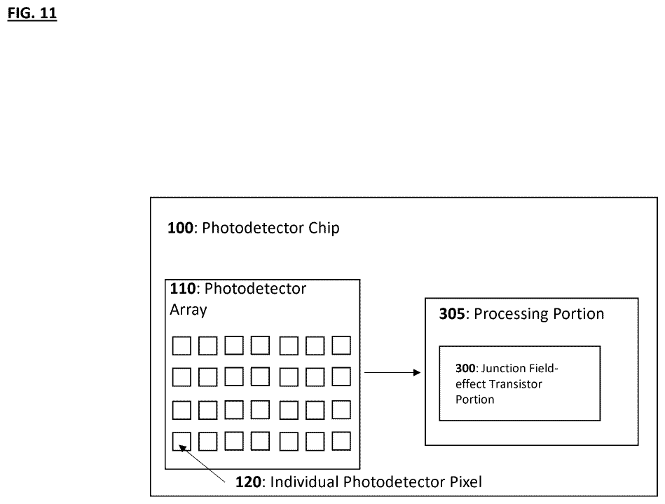

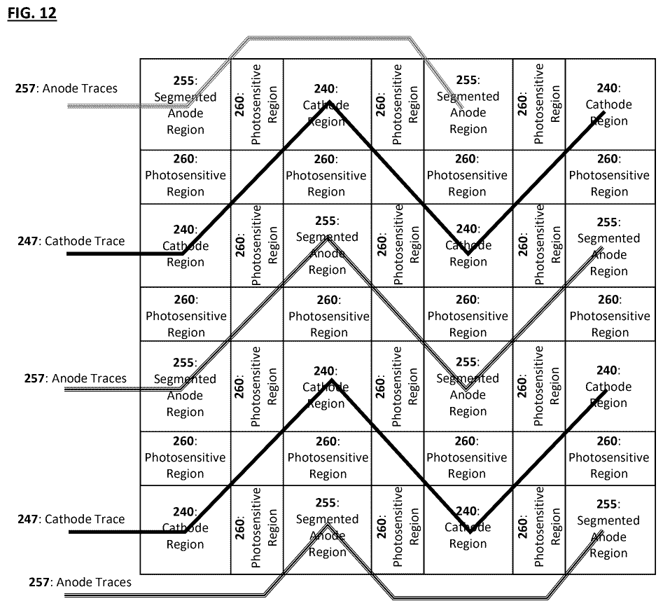

As depicted in FIG. 10, in embodiments a photodetector array 110 may be structured from a plurality of photodetector pixels 120, with each individual photodetector pixel 120 comprising a photodiode portion 200 that is connected to a processing portion 305, were the processing portion 305 performs processing, such as amplification, on the output of the photodiode portion 200. In other embodiments, as depicted in FIG. 11, the photodetector array 110 may be formed from individual photodetector pixels 120 that do not comprise processing portions 305, where the individual photodetector pixels 120, each comprising a cathode region 240, and anode region 250, and a photosensitive region 260, are connected through any of a variety of interconnection schemes (explained below in reference to FIG. 12-FIG. 15) to processing portion 305 that is located outside of the photodetector array 110.

A variety of interconnection schemes may be considered to connect the individual photodetector pixels 120 to the processing portion 305. In embodiments, as depicted in FIG. 12, cathode regions 240 are mutually connected, and connected to ground (not shown) through cathode traces 247. In embodiments those cathode traces 247 may be made narrow, so as to minimize the areas of the photosensitive regions 260 that are blocked thereby. In embodiments the cathode traces 247 may be routed to minimize overlying of photosensitive regions 260, where the routing may be as, for example, shown in FIG. 12. In embodiments the cathode traces 247 may be formed from UV-transparent or semitransparent conductive materials, such as, for example, indium tin oxide (ITO), zinc oxide (ZnO), tin oxide (SnO₂), graphene thin film, transparent conductive polymers, extremely thin layers of metal such as gold, or the like. Embodiments may combine these strategies for minimizing the occlusion of the photosensitive regions 260. Methods for forming ohmic contacts between the cathode traces 247 and the cathode regions 240, and for insulating between the cathode traces 247 and non-contact surfaces may be as described below in reference to FIG. 17.

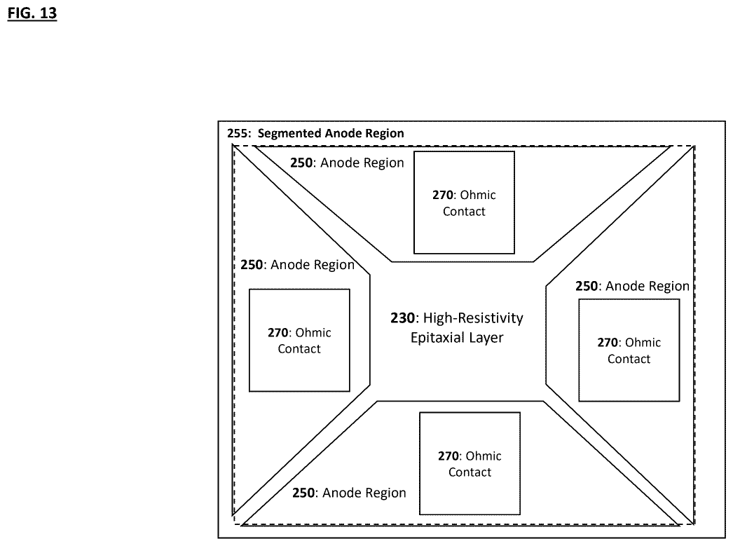

In embodiments, the segmented anode regions 255 depicted in FIG. 12 each comprises a plurality of anode regions 250, each facing a corresponding cathode region 240 across a photosensitive region 260, as depicted in FIG. 13. The individual anode regions 250 in the segmented anode region 255 are separated from each other by, in embodiments, the high-resistivity epitaxial layer 230. In other embodiments the individual anode regions 250 in the segmented anode region 255 are isolated from each other by trenches, trenches filled with an insulator, or the like. A single photodetector pixel 120 is formed by the combination of an anode region 250 (depicted in FIG. 13), the opposing cathode region 240 (shared by multiple photodetector pixels 120, as depicted in FIG. 12), and the photosensitive region 260 that is interposed therebetween.

Returning to FIG. 12, anode traces 257 are provided to lead out from each of the ohmic contact 270 of each individual anode region 250 in each segmented anode region 255. Unlike the cathode traces 247 that are illustrated in FIG. 12, which, in embodiments, is each a single trace that connects multiple cathode regions 240, the anode traces 257 illustrated in FIG. 12 each comprises a plurality of individual traces, each connecting a single anode region 250 to the processing portion 305 (illustrated in FIG. 11) that is outside of the photodetector array 110. In embodiments, these anode traces 257 may be formed from the same materials, and routed with the same strategy, as for the cathode traces 247 that were explained above.

While FIG. 12 shows a photodetector array 110 that has a total of 24 photodetector pixels 120, there is no limitation thereto, where this photodetector array 110 structure is scalable to an arbitrary number of photodetector pixels 120.

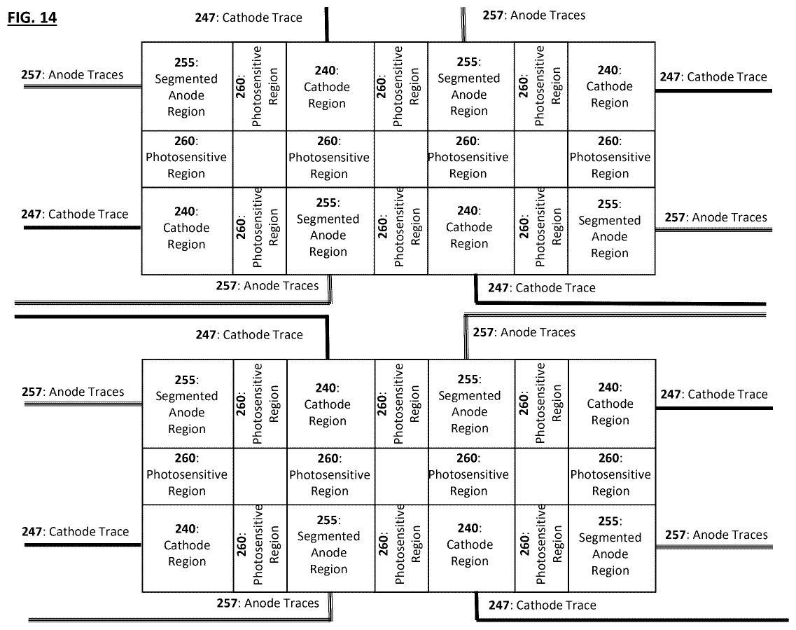

FIG. 14 depicts an interconnection scheme of another embodiment. As depicted in FIG. 14, in a photodetector array 110 of an embodiment spaces are left, between regions wherein photodetector pixels 120 are formed, to enable the cathode traces 247 and the anode traces 257 to be routed without occluding any photosensitive regions 260. As with the photodetector array 110 structure depicted in FIG. 12, this photodetector array 110 structure is also arbitrarily scalable.

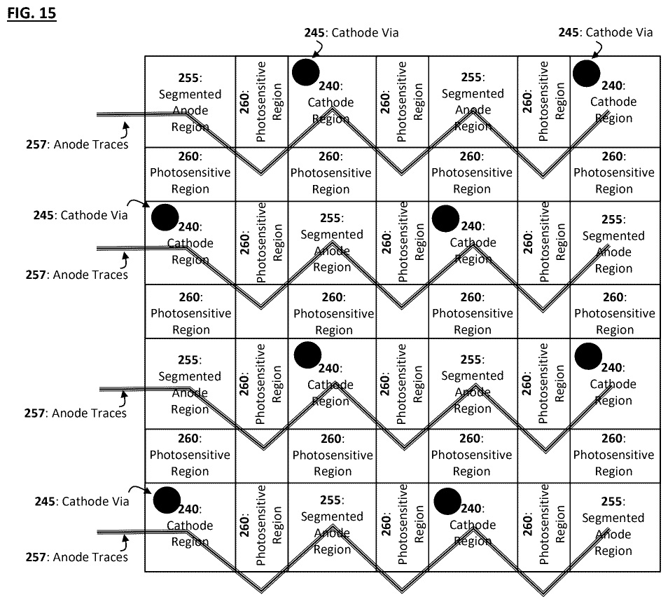

FIG. 15 depicts a photodetector array 110 of yet another embodiment. In the embodiment depicted in FIG. 15 the cathode regions 240 are all grounded through cathode vias 245 to a back plane, not shown, simplifying the geometries of the interconnections, and reducing the occlusion of the photosensitive regions 260. Note that for convenience in illustration, not all of the cathode vias 245 that are illustrated are numbered.

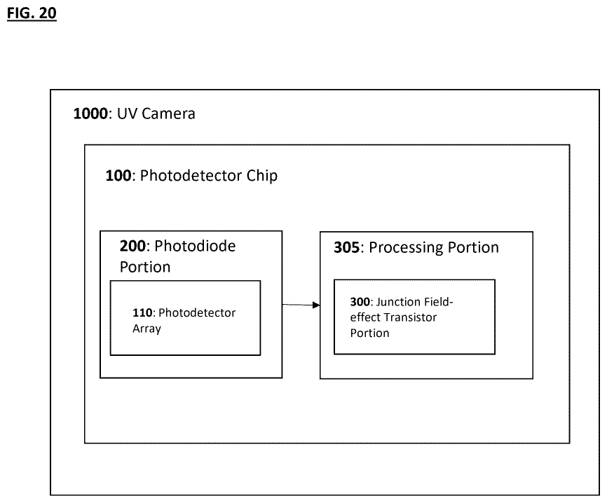

In embodiments, the combination of a multipixel photodetector array 110 with frequency-specific UV bandpass filters, such as the first-frequency UV bandpass filter 290 and the second-frequency UV bandpass filter 292 that are depicted in FIG. 9, enables a multifrequency 2D photodetector array 110 that can be used as the photosensitive element in a UV camera 1000, as depicted in FIG. 20, able to capture “color pictures” in the UV domain, with colors that are mixed and mapped onto an RGB color gamut for display or printing, greatly enhancing the information richness from the UV sensors.

The structures of the junction field-effect transistor portion 300, and of the photodiode portion 200, of embodiments will be understood through the description of the manufacturing method, of an embodiment, that will be described next in reference to FIG. 16A through FIG. 16I which show cross-sectional diagrams of relevant portions of a SiC photodetector at various stages in the manufacturing process thereof, along with providing a flow chart for a method for manufacturing the SiC photodetector. The structures and processing steps depicted therein are to be understood to be non-limiting, as mere embodiments.

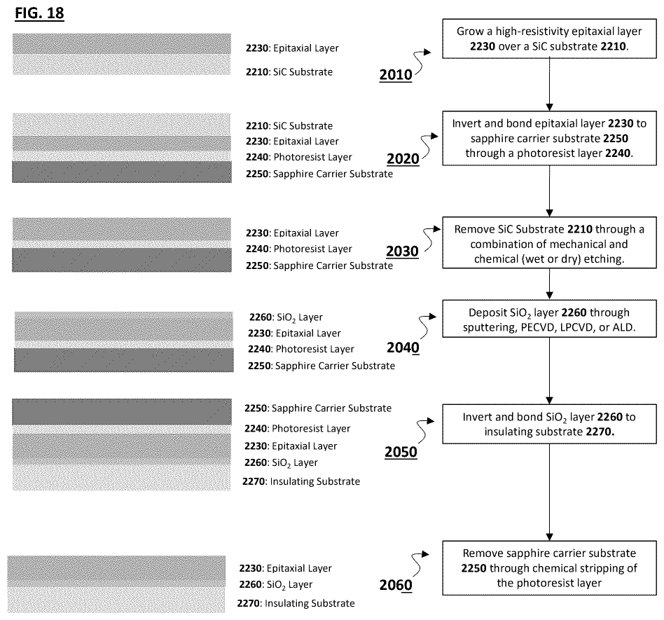

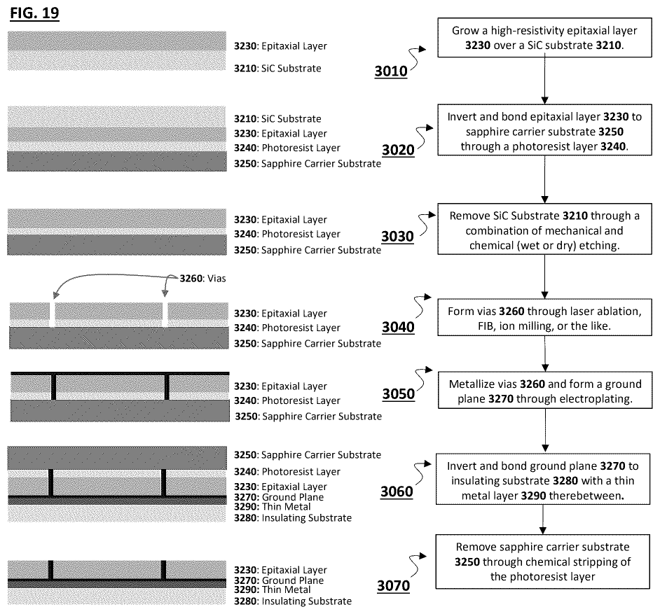

Referring first to FIG. 16A, in embodiments the photodetector is built on a substrate, which, in embodiments, may be a silicon carbide (SiC) substrate 210, which, in embodiments, may be a 4H or 6H silicon carbide wafer, which, in embodiments, may be an n-type 4H or 6H SI silicon carbide wafer. In other embodiments, the SiC substrate may be a high-resistivity(unintentionally-doped) 4H silicon carbide wafer. In embodiments, a high-resistivity epitaxial layer 230 (a high-resistivity silicon carbide epitaxial layer) is grown 1010 (high-resistivity epitaxial growth step) over the SiC substrate 210, to provide a high-resistivity layer in which to build the photodiode portion. In embodiments wherein the substrate is doped with a p-type dopant or an n-type dopant, an epitaxial layer of the opposite conductivity type 220 (referencing FIG. 2) may be grown (low-resistivity epitaxial growth step) over the SiC substrate 210 prior to growth 1010 of the high-resistivity epitaxial layer 230, to thereby provide a p-n junction to the back surface. The epitaxial layers may be grown through known epitaxial deposition techniques, such as the use of chemical vapor deposition, sublimation epitaxy, molecular beam epitaxy, liquid-phase epitaxy, epitaxial lateral overgrowth, hydride vapor phase epitaxy, or the like, with no particular limitations. In embodiments, the high-resistivity SiC epitaxial layer may have a thickness of between 5 and 25 μm, although there is no particular limitation thereto. As will be described below in reference to FIG. 18 and FIG. 19, in other embodiments, the substrate is thinned down to the point of complete removal, leaving only the high-resistivity epitaxial layer that contains the devices. This resultant layer can be either affixed to an insulating substrate such as silica, or an insulating layer can be grown on the back of the substrate, thereby forming a SiC-on-insulator material system that provides further thermal and potentially radiation ruggedness.

As depicted in FIG. 16A, after growth 1010 of the high-resistivity epitaxial layer 230 over the SiC substrate 210, an n well-forming hard mask 420, for forming an n well 310, is then deposited and patterned 1020. The hard mask 420 will serve as a mask during the subsequent ion implantation 1030 step, and may be formed from any of a variety of materials such as silicon dioxide, silicon nitride, silicon oxynitride, aluminum oxide, tungsten, or titanium, which, depending on the material, may be grown through thermal oxidation, chemical vapor deposition, low-pressure chemical vapor deposition, plasma-enhanced chemical vapor deposition, atomic layer deposition, physical vapor deposition, sputtering, or the like. These techniques are well known in the art, and need not be described further here.

As depicted in FIG. 16A, following deposition of the n well-forming hard mask 420, in embodiments the n well-forming hard mask 420 is patterned, using a known patterning technique, such as the use of a photolithographic mask followed by etching, to open windows to the high-resistivity epitaxial layer 230 over the areas wherein the n well 310 is to be formed. As described above in reference to FIG. 5, in embodiments the n well 310 provides an n-type region in the high-resistivity epitaxial layer 230 for forming a junction field-effect transistor that has a dual n+ gate 320, a p+ source 330, and a p+ drain 340. Note that in embodiments the n well 310 is provided only in the p-type JFET portion 301 of the JFET portion 300; in embodiments there is no need for an n well in the photodiode portion 200 nor in the n-type JFET portion 302 of the JFET portion 300.

As depicted in FIG. 16A, after deposition and patterning 1020 of the n well-forming hard mask 420, in embodiments n-type (donor) ion implantation (a first ion implantation step) is performed. In embodiments, this ion implantation may use phosphorus ions (donor ions) as the n-type species, and in embodiments heated phosphorus ion implantation 1030 may be performed. Note that the species that is implanted is not limited to phosphorus, but may be any suitable ion that can act as a donor ion in SiC. Performing ion implantation into a heated substrate reduces dislocations and other damage, and provides an annealing process during the implantation step. Note that the dose of the implantation is selected to produce a lightly-doped n well region, where “light ion implantation” or “lightly-doped” in this specification shall be taken to mean a peak dopant concentration that is at least an order of magnitude greater than that of the unintentionally-doped semiconductor, described above, and at least an order of magnitude less than that of the “heavily-doped” regions, described below. In embodiments, “heavily-doped” may be such that the peak concentration will be between 10¹⁹ and 10²⁰ cm⁻³. In embodiments, the dose of the heated light phosphorus ion implantation 1030 may be such that the peak concentration will be between 10¹⁶ and 10¹⁷ cm⁻³. In embodiments, the heating of the substrate 210 during ion implantation may be at about 600° C.

Following the light phosphorous ion implantation 1030, in embodiments the n well-forming hard mask 420 is removed 1040, as depicted in FIG. 16B. In embodiments, this removal may be through an etching process, with the etchant selected depending on the material from which the hard mask is formed. In embodiments, the etchant has high selectivity to enable etching of the n well-forming hard mask 420 with relatively little etching of the underlying material. In embodiments the removal of the n well-forming hard mask 420 may use, without limitation, a dry etching process, a wet etching process, plasma etching, laser ablation, CMP, and the like.

As depicted in FIG. 16B, following the removal 1040 of the n well-forming hard mask 420, in embodiments a p channel-forming hard mask 440, for forming the p channel region 350, is deposited and patterned 1050, using the same technique as described above, to produce a p channel-forming hard mask 440 that has windows opened over the regions wherein the p channel region 350 is to be formed.

As depicted in FIG. 16B, after deposition and patterning 1050 of the p channel-forming hard mask 440, in embodiments p-type (acceptor) ion implantation (a second ion implantation step) is performed. In embodiments, this ion implantation may use aluminum ions as the p-type species, and in embodiments heated aluminum ion implantation 1060 may be performed. Note that, as described above, the species that is implanted is not limited to aluminum, but may be any suitable ion that can act as an acceptor ion in SiC.

After the light aluminum ion implantation 1060, in embodiments the p channel-forming hard mask 440 is removed 1070, as depicted in FIG. 16C. In embodiments, this removal may be through a process as described above for the removal of the n well-forming hard mask 420.

As depicted in FIG. 16C, after the removal 1070 of the p channel-forming hard mask 440, a p well-forming hard mask 460, for forming a p well 360, is then deposited and patterned 1080. The p well-forming hard mask 450 will serve as a mask during the subsequent ion implantation 1090 step, and, in embodiments, may be formed in the same manner as described above.

As depicted in FIG. 16C, following deposition of the p well-forming hard mask 460, in embodiments the p well-forming hard mask 460 is patterned, using a known patterning technique, such as the use of a photolithographic mask followed by etching, to open windows to the high-resistivity epitaxial layer 230 over the areas wherein the p well 360 is to be formed. As described above in reference to FIG. 5, in embodiments the p well 360 provides a p-type region in the high-resistivity epitaxial layer 230 for forming a junction field-effect transistor that has a dual p+ gate 370, an n+ source 380, and an n+ drain 390. Note that in embodiments the p well 360 is provided only in the n-type JFET portion 302 of the JFET portion 300; in embodiments there is no need for a p well in the photodiode portion 200 nor in the p-type JFET portion 301 of the JFET portion 300.

As depicted in FIG. 16C, after deposition and patterning 1080 of the p well-forming hard mask 460, in embodiments p-type (acceptor) ion implantation (a third ion implantation step) is performed. In embodiments, this ion implantation may use aluminum ions (acceptor ions) as the p-type species, and in embodiments heated light aluminum ion implantation 1090 may be performed. Note that the species that is implanted is not limited to aluminum, but may be any suitable ion that can act as an acceptor ion in SiC. As noted above, performing ion implantation into a heated substrate reduces dislocations and other damage, and provides an annealing process during the implantation step.

Following the light aluminum ion implantation 1090, in embodiments the p well-forming hard mask 460 is removed 1100, as depicted in FIG. 16D. In embodiments, this removal may be performed in a manner described above.

As depicted in FIG. 16D, following the removal 1100 of the p well-forming hard mask 460, in embodiments a n channel-forming hard mask 480, for forming the n channel region 351, is deposited and patterned 1120, using the same technique as described above, to produce a n channel-forming hard mask 480 that has windows opened over the regions wherein the n channel region 351 is to be formed.

As depicted in FIG. 16D, after deposition and patterning 1120 of the n channel-forming hard mask 480, n-type (donor) ion implantation (a fourth ion implantation step) is performed. In embodiments, this ion implantation may use phosphorous ions as the n-type species, and in embodiments heated phosphorous ion implantation 1130 may be performed. Note that, as described above, the species that is implanted is not limited to phosphorous, but may be any suitable ion that can act as a donor ion in SiC. In embodiments, the dose of the heated light donor ion implantation 1130 may be such that the peak concentration will be between 10¹⁶ and 10¹⁷ cm⁻³, and the heating of the substrate 210 during heated light phosphorous ion implantation 1130 may be to about 600° C.

Following this, in embodiments, as depicted in FIG. 16E, the n channel-forming hard mask 480 may be removed 1140 using a hard mask removing process similar to that which has been described above in relation to the removal 1040 of the n well-forming hard mask 420.

Note that, in embodiments, a self-aligning hard mask, with windows open to both the n well region 310 and the p well region 360, may be deposited and patterned prior to deposition of the n well-forming hard mask 420, with the n well-forming hard mask 420, the p channel-forming hard mask 440, and the p well-forming hard mask 460 deposited and patterned thereover, to provide enhanced dimensional control. In embodiments this self-aligning hard mask is removed either simultaneously with, or subsequent to, removal 1100 of the p well-forming hard mask 460. In embodiments the formation and patterning 1050 of the p channel-forming hard mask 440 and the implantation of aluminum ions 450 therethrough, depicted in FIG. 16B, may be performed instead after the formation and patterning 1080 of the p well-forming hard mask 460 and the implantation of aluminum ions 470 therethrough that is depicted in FIG. 16C, with a self-aligning hard mask, with windows open to the both the p channel region 350 and the n channel region 351 formed under the p channel-forming hard mask 440 and the n channel-forming hard mask 480, to provide enhanced dimensional control.

As depicted in FIG. 16E, in embodiments, following removal 1140 of the n channel-forming hard mask 480, a anode-forming hard mask 500 for heavy p-type (acceptor) ion implantation 1160 is deposited and patterned 1150. The anode-forming hard mask 500 may be deposited and patterned in the same manner as described above, so further details are omitted here. This anode-forming hard mask 500 is formed so as to open windows over regions into which heavy p-type implantation 1150 is to be carried out, which are, specifically, the regions that are to form the anode region 250 (a heavily doped p-type anode region formed in the high-resistivity silicon carbide epitaxial layer) in the photosensitive region 260, and the p+ source and drain regions 330 and 340 in the p-type JFET portion 301 and the p+ gate region 370 in the n-type JFET portion 302 in the JFET portion 300. Note that this provides the synergy of doping the anode region 250 in the photosensitive region 260 as part of the process of fabricating the JFET transistor portion 300, without requiring any additional processing whatsoever.

As depicted in FIG. 16E, in embodiments after deposition and patterning 1150 of the anode-forming hard mask 500, heavy p-type (acceptor) ion implantation (a fifth ion implantation process) is carried out. In embodiments, aluminum ions may be used as the p-type dopant in a heated heavy aluminum ion implantation 1160. In embodiments, the heating of the substrate 210 in the heavy aluminum ion implantation 1160 may be to about 600° C. Note that here, as above, “heavy ion implantation” is meant to denote ion implantation with a dose that is at least one order of magnitude greater than the dose that is described above as “light ion implantation.” In embodiments, the dose of the heated heavy aluminum ion implantation 1160 may be such that the peak concentration will be between 10¹⁹ and 10²⁰ cm⁻³. In embodiments, the effective depth of the heated heavy aluminum ion implantation 1160 for source and drain ion implantation may be about 400 nm.

Following this, as depicted in FIG. 16F, in embodiments the anode-forming hard mask 500 may be removed 1170 using a hard mask removing process similar to that which has been described above in relation to the removal 1040 of the n well-forming hard mask 420.

Following removal 1180 of the anode-forming hard mask 500, as depicted in FIG. 16F, in embodiments a cathode-forming hard mask 520 for heavy n-type (donor) ion implantation 1190 is deposited and patterned 1180. The cathode-forming hard mask 520 may be deposited and patterned in the same manner as described above, so further details are omitted here. This cathode-forming hard mask 520 is formed so as to open windows over regions into which heavy n-type (donor) ion implantation 1190 is to be carried out, which are, specifically, the regions that are to form the cathode region 240 in the photosensitive region 260 (a heavily doped n-type cathode region formed in the high-resistivity epitaxial layer 230), and the n+ source and drain regions 380 and 390 in the n-type JFET portion 302 and the p+ gate region 370 in the p-type JFET portion 301 in the JFET portion 300. Note that this provides the synergy of doping the cathode region 240 in the photosensitive region 260 as part of the process of fabricating the JFET transistor portion 300, without requiring any additional processing whatsoever.

As depicted in FIG. 16F, in embodiments, after deposition and patterning 1180 of the cathode-forming hard mask 520, heavy n-type (donor) ion implantation (a sixth ion implantation process) is carried out. In embodiments, phosphorous or nitrogen ions may be used as the n-type (donor) dopant in a heated heavy phosphorous or nitrogen ion implantation 1190. In embodiments, the heating of the substrate 210 in the heavy phosphorous or nitrogen ion implantation 1190 may be to about 600° C. In embodiments, the dose of the heated heavy phosphorous or nitrogen ion implantation 1190 may be such that the peak concentration will be between 10¹⁹ and 10²⁰ cm⁻³. In embodiments, the effective depth of the heated heavy phosphorous or nitrogen ion implantation 1190 for source/drain ion implantation may be about 400 nm.

Following this, as depicted in FIG. 16G, in embodiments the cathode-forming hard mask 520 may be removed 1200 using a hard mask removing process similar to that which has been described above in relation to the removal of the first through anode-forming hard masks, described above.

Note that while in the above a specific sequence was given with the implantation 1160 of the p+ regions performed first and the implantation 1190 of the n+ regions performed thereafter, there is no limitation thereto; the implantation 1190 of the n+ regions may be performed prior to the implantation 1160 of the p+ regions. In the present specification, the terms “fifth,” “sixth,” and the like, do not necessarily imply a specific sequence, but rather an arbitrary sequence may be used insofar as the sequence selected is compatible with the effects required in the processing steps.

Note also that, in embodiments, a self-aligning hard mask, not numbered, with windows open to both the n+ regions and the p+ regions, may be deposited and patterned prior to deposition of the anode-forming hard mask 500, with the anode-forming hard mask 500 and the cathode-forming hard mask 520 deposited and patterned thereover, to provide enhanced dimensional control. In embodiments this self-aligning hard mask is removed either simultaneously with, or subsequent to, removal 1200 of the cathode-forming hard mask 520.

As depicted in FIG. 16G, in embodiments, following the removal 1200 of the cathode-forming hard mask 520, a pre-anneal clean 1210 is performed. This is to remove any contaminants that otherwise might be diffused into the substrate 210 during the anneal process. The pre-anneal clean 1210 may use any of a variety of well-established processes, such as an RCA cleaning process (immersion in ammonium hydroxide, hydrogen peroxide, and deionized water to remove organic contaminants, followed by immersion in hydrochloric acid, hydrogen peroxide and deionized water to remove metallic contaminants), a piranha cleaning process (immersion in sulfuric acid and hydrogen peroxide), a hydrofluoric acid dip followed by rinsing in deionized water, megasonic cleaning, ozone treatment, or the like, as is well known in the art.

As depicted in FIG. 16G, in embodiments, following the pre-anneal clean 1210, in embodiments amorphous carbon or aluminum nitride (a thermally stable material) 600 is deposited 1220 to form an anneal cap 610. In other embodiments, other thermally stable materials such as AlN/BN or graphite may be used for the anneal cap 610. This anneal cap 610 impedes step-bunching-induced roughening of the surface during annealing that would be caused through sublimation at high temperatures. A high temperature anneal 1230 is then carried out to activate the implanted ions. In embodiments, the anneal is carried out for between one and two hours in an inert ambient, such as an argon ambient, at a temperature between 1675 and 1800° C. In embodiments, the anneal cap 610 is then removed 1240 through oxygen plasma ashing or thermal oxidation at high temperatures, leaving the structure depicted in FIG. 16H.

As depicted in FIG. 16H, in embodiments, following removal 1240 of the anneal cap 610, a contact-forming hard mask 620, for ohmic metal deposition 1250 and also serving as an insulating layer, is deposited and patterned 1240, using, in embodiments, processes similar to those described above for the first through cathode-forming hard masks, and windows are opened over at least portions of the anode region 250 and cathode region 240 of the photodiode portion 210, and over at least portions of the n+ gates 320, p+ source 330, p+ drain 340, p+ gates 370, n+ source 380, and n+ drain 390 in the JFET portion 300. A metal for forming an ohmic contact is then deposited 1260. In embodiments, this metal for forming an ohmic contact may be, for example, nickel, titanium, platinum, tungsten, aluminum, or an alloy thereof. In the embodiment illustrated in FIG. 16H, deposited nickel 630 is used as the metal for forming an ohmic contact. In embodiments, the ohmic metal may be deposited to a thickness of, for example, about 100 nm.

In embodiments, a high temperature annealing/silicidation process 1270 is then performed to form a silicide that will form ohmic contacts 640 (silicide contacts) with the anode region 250 and cathode region 240 of the photodiode portion 210, and with the n+ gates 320, p+ source 330, p+ drain 340, p+ gates 370, n+ source 380, and n+ drain 390 (transistor contact areas) in the JFET portion 300, as depicted in FIG. 16H. This high temperature anneal/silicidation 1270 may be performed at, for example, about 950° C. for about three minutes in an inert ambient, which, in embodiments, may be argon or nitrogen.

Following this, as depicted in FIG. 16I, in embodiments the unreacted metal is removed 1280, to leave behind silicide ohmic contacts 640. This removal 1280 of the unreacted metal may be achieved through the use of an etchant that preferentially attacks metals over silicides and silicon, such as sulphuric peroxide or Piranha solutions.

Note that the remaining portion of the contact-forming hard mask 620 is not removed. This is because the remaining portion of the contact-forming hard mask 620 also functions as an insulating layer between the active elements in the photodiode portion 200 and the JFET portion 300 and a metallization layer that is to be formed thereabove.

In embodiments, as depicted FIG. 16I, the portions of the contact-forming hard mask 620 that remain over the photosensitive regions 260 are removed 1290. In embodiments the removal 1290 of those portions of the contact-forming hard mask 620 may be achieved through the same photolithography and etching processes, or the like, used in patterning hard masks as described above. Removal 1290 of those portions of the contact-forming hard mask 620 prevent the contact-forming hard mask 620 from occluding light that would impinge on the photosensitive regions 260.

In embodiments contact metallization and deposition of an interconnection metallization layer 1300 are then carried out as is conventionally done in semiconductor processing. Although the contact and interconnection processes 1300 need not be described in detail, in embodiments these processes may comprise depositing 200 nm of TiW to make metal contacts to the silicide ohmic contacts 640, followed by photoresist patterning and etching to remove unneeded TiW, followed by forming a photoresist pattern for the top metal, depositing a compound top metal stack, which, in embodiments, may be Ti (25 to 75 nm)/Pt (100 to 300 nm)/Au (0.5 to 1 μm) or Ti (10 to 20 nm)/TaSi2 (100 to 300 nm)/Pt (0.5 to 1 μm), and then performing a lift-off process.

Note that the light n-type doped regions, the light p-type doped regions, the heavy n-type doped regions, and the heavy p-type doped regions in the embodiments above are not limited to having those functions that are described above (specifically, to functioning as the anode region 250 and cathode region 240 of the photodiode portion 210, and as the n+ gates 320, p+ source 330, p+ drain 340, p+ gates 370, n+ source 380, and n+ drain 390 in the JFET portion 300), but rather, in embodiments, may also be configured to function as other circuit elements, such as resistors, diodes, capacitors, and the like, enabling the design of complex circuitry on the same semiconductor chip as the photodiode portion 200. This enables amplification of the detected UV signal prior to outputting to an external circuit.

Note that in the contact and interconnection processes 1300, the photolithographic masks are designed so as to interconnect components following specific circuit patterns to produce a variety of circuit designs, including at least connecting the cathode regions 240 and anode regions 250 of parallel- or serial-connected photodiode portions 200 to gates 320 and/or 370 of JFET portions 301 and/or 302 that are interconnected so as to form a transimpedance amplifier, to thereby amplify the output of the photodiode portions 200.

In embodiments, UV bandpass filters 290 and 292, not shown, may be deposited over a subset of the photosensitive regions 260, with patterned metal interconnect layers 280 configured so as to connect subsets of photosensitive regions 260 to structure a selective UV band-pass or multifrequency UV sensor, enabling finer monitoring of combustion byproducts and control of combustion inputs, for, for example, industrial processes and an afterburner in a fighter jet. The processes for forming these UV bandpass filters 290 and 292 will be described in reference to the process flow diagrams and structure diagrams of FIG. 17. As depicted in FIG. 17, in embodiments a stack 700 of one or more dielectric layers is deposited 1400 over the photodiode portion 200, which, in embodiments comprises a first photodiode portion 202 and a second photodiode portion 204. In embodiments this may be performed after removal of the carbon cap in step 1240 depicted in FIG. 16H. Note that there is no particular limitation to the number of photodiode portions; the number of photodiode portions may be selected arbitrarily as needed to provide a photodetector with the wavelength resolution required for the particular application. In embodiments, the deposition of the stack 700 may be over the processing portion 305 as well. In embodiments, a hard mask (not shown) may be formed prior to deposition of the stack 700, enabling use of the hard mask in patterning the stack 700 later through a lift-off process. In embodiments the materials of the dielectric layers are selected based on refractive indexes and absorption coefficients so as to form a band pass filter with sufficient transmission in the desired wavelength range while being adequately opaque in non-desired wavelength ranges. In embodiments the thicknesses of the dielectric layers may be selected to provide desirable positive and/or negative interference effects to achieve the desired band pass characteristics. In embodiments the individual dielectric layers in the stack may be deposited through physical vapor deposition or chemical vapor deposition (for example, low pressure chemical vapor deposition, atomic layer deposition, sputtering, and the like). In embodiments a photolithographic process may be used to pattern 1410 the stack 700 into the filter 290 over the first photosensitive region 202, while leaving the second photosensitive region 204 exposed. In embodiments a similar process 1420 and 1430 may be used to form a filter 292 over the second photosensitive region 204 that is not covered by the filter 290. In embodiments, the filter 290 may be covered by a protective material (either sacrificial or transparent) prior to the formation of the filter 292, so as to allow the fabrication and patterning of a stack 702 for the filter 292 without affecting the filter 290. In other embodiments, such processing steps may be combined and resequenced to allow some dielectric layers to be deposited simultaneously for use in both the filter 290 and the filter 292. In other embodiments, a material layer deposited in the regions for forming both filters 290 and 292 may be removed selectively, in whole or in part, from the region of the filter 292, for example, to form the filter 292. In embodiments the structures of the stacks 700 and 702 for filters 290 and 292 are designed with dielectric layers with materials and thicknesses to provide the filters 290 and 292 with respectively differing optical characteristics. Note that there are no limitations to UV bandpass filters 290 and 292 made through the embodiment described above. There is also no limitation to having only two different moieties of bandpass filter, rather UV bandpass filters of three different frequency bands may be provided, with the outputs thereof mixed to as to produce a trichroic optical element, and in embodiments the outputs of this element may be mixed and mapped into an RGB color gamut for use in producing false-color images for displaying UV-domain radiation intensity. Furthermore, there is no limitation to just three frequency bands of bandpass filters, but rather UV bandpass filters of four or more different pass bands may be provided, allowing the user to switch between frequency domains as required, greatly enhancing the information richness of the UV sensor system.

While in the embodiments described above, the high-resistivity epitaxial layer 230 was grown on the substrate 210, of, for example, a 4H or 6H silicon carbide wafer, the processing portion 305 and the photodiode portion 200 were formed therein while high-resistivity epitaxial layer 230 is still in contact with the substrate 210, there is no limitation thereto. The high-resistivity epitaxial layer 230 being on a conductive substrate 210 has drawbacks; an insulating substrate is preferred over a conductive substrate 210 in terms of thermal durability and radiation resistance. However, deposition of an epitaxial SiC layer onto an insulating substrate, such as SiO₂ or sapphire, is not feasible due to a large mismatch in lattice constant, a mismatch in coefficients of thermal expansion, poor chemical compatibility, challenges in preparing defect-free and contamination-free surfaces of the insulating substrates, and the like. In embodiments these difficulties can be overcome through providing an insulating substrate to substitute for the SiC substrate. An embodiment for fabrication of such a structure will be explained in reference to FIG. 18.

As depicted in FIG. 18, in embodiments, the SiC substrate 210 (2210) may be replaced with an insulating substrate 2270, which provides benefits of electrical isolation and radiation hardening. In embodiments this is achieved through the method illustrated in FIG. 18. In embodiments an epitaxial layer 2230 is first grown 2010 on a SiC substrate, in the same manner as in the embodiments described above in reference to FIG. 16, and in embodiments photodiode portions 200 and processing portions 305 are then fabricated in the epitaxial layer 2230 through, for example, the steps indicated by 1010 though 1240 illustrated in FIG. 16A through FIG. 16H. Note that in the state following the step indicated by 1240, the epitaxial layer 2230 (230) and various doped regions in the epitaxial layer 2230 (230) are exposed, with no mask layer present thereon. For convenience in drawing and explanation, these various doped regions of the photodiode portions 200 and processing portions 305 are omitted from FIG. 18. As shown in FIG. 18, in embodiments this epitaxial layer 2230 is bonded 2020 to a sapphire carrier substrate 2250 through a photoresist layer 2240, where the photoresist layer 2240 serves to bond the epitaxial layer 2230 to the sapphire carrier substrate 2250. Note that there is no limitation to the use of a sapphire carrier substrate 2250, but another substrate, such as a SiO₂ carrier substrate, may be used instead in other embodiments. With the layered structure now supported by the sapphire carrier substrate 2250, in embodiments the original SiC substrate 2210, which was used to define the crystal matrix for the epitaxial deposition of the epitaxial layer 2230, is then removed 2030 through a combination of mechanical and chemical etching (wet or dry), leaving a high-resistivity single crystal SiC epitaxial layer 2230 that is bonded to and supported by the sapphire carrier substrate 2250. In embodiments, an amorphous SiO₂ layer 2260 is then deposited 2240, onto the epitaxial layer 2230, through sputtering, PECVD, LPCVD, or ALD, which is then bonded 2050 through direct or fusion bonding to an insulating substrate 2270, which, in embodiments, may be of sapphire, silica, or the like. This SiO₂ layer 2260 has the role of facilitating adhesion of the epitaxial layer to the insulating substrate 2270. Finally the sapphire carrier substrate 2250 and the photoresist layer 2240 are removed 2060 through chemical stripping of the photoresist layer, leaving the single-crystal epitaxial layer 2230 bonded to the insulating substrate 2270 with the SiO₂ layer 2260 therebetween. In embodiments, photodiode portions 200 and processing portions 305 are then fabricated in the epitaxial layer 2230 in the same manner as in the embodiments set forth above in reference to FIG. 16. In embodiments, the processing steps indicated in 2020 through 2060, depicted in FIG. 18, may be performed at any point following the removal of the carbon cap 1240.

Another layer structure that can be used in embodiments of a SiC UV photodetector is depicted in FIG. 19, where, in addition to replacing the SiC substrate 210 (3210) with an insulating substrate 3280, vias 3260 are provided penetrating through the epitaxial layer 230 (3230), connecting to a ground plane 3270, which provides benefits of reducing device footprint by obviating the need for an additional manifold on the top of the epitaxial layer. In embodiments this is achieved through the method illustrated in FIG. 19. As depicted in FIG. 19, in embodiments, an epitaxial layer 3230 is first grown 3010 on a SiC substrate, in the same manner as in the embodiments described above in reference to FIG. 16, and in embodiments photodiode portions 200 and processing portions 305 are then fabricated in the epitaxial layer 3230 through, for example, the steps indicated by 1010 through 1240 illustrated in FIG. 16A through FIG. 16H. Note that in the state following the step indicated by 1240, the epitaxial layer 3230 (230) and various doped regions in the epitaxial layer 3230 (230) are exposed, with no mask layer present thereon. For convenience in drawing and explanation, these various doped regions of the photodiode portions 200 and processing portions 305 are omitted from FIG. 19. As shown in FIG. 19, in embodiments this epitaxial layer 3230 is bonded 3020 to a sapphire carrier substrate 3250 through a photoresist layer 3240, where the photoresist layer 3240 serves to bond the epitaxial layer 3230 to the sapphire carrier substrate 3250. Note that, as was the case in the embodiments set forth in reference to FIG. 18, there is no limitation to the use of a sapphire carrier substrate 3250, but another substrate, such as a SiO₂ carrier substrate, may be used instead in other embodiments. With the layered structure now supported by the sapphire carrier substrate 3250, in embodiments the original SiC substrate 3210, which was used to define the crystal matrix for the epitaxial deposition of the epitaxial layer 3230, is then removed 3030 through a combination of mechanical and chemical etching (wet or dry), leaving a high-resistivity single crystal SiC epitaxial layer 3230 that is bonded to and supported by the sapphire carrier substrate 3250.

In embodiments, the vias 3260 are formed 3040 through the epitaxial layer 3230 through laser ablation, FIB (focused ion beam), ion milling, or the like. Following this, a metallization process, such as electroplating 3050, is carried out to metallize the vias 3260 and form a ground plane 3270 over the epitaxial layer 3230. This ground plane 3270 will provide a conductive back-face surface on the final device, along with providing enhanced protection from radiation and electromagnetic pulses. The ground plane 3270 is then bonded 3060 through thermocompression bonding to a thin metal layer 3290 that is formed on an insulating substrate 3280, which, in embodiments, may be of sapphire, silica, or the like. This thin metal layer 3290 is provided to facilitate bonding of the insulating substrate to the ground plane. Finally the sapphire carrier substrate 3250 and the photoresist layer 3240 are removed 3070 through chemical stripping of the photoresist layer. The result is a layered structure having a high-resistivity epitaxial layer 3230 as an active layer in which to fabricate the photodiode portions 200 and processing portions 305, described above, in the same manner as in the embodiments set forth above in reference to FIG. 16, while also having the ground plane 3270 to provide a back-plane conductive path, and to provide protection from radiation and electromagnetic pulse, where this back-plane conductive path is accessible through the vias 3260. This provides a structure that enables lower device footprint and, in some cases, a path to thermal ground for removing excess heat. In embodiments, photodiode portions 200 and processing portions 305 are then fabricated in the epitaxial layer 3230 in the same manner as in the embodiments set forth above in reference to FIG. 16. In embodiments, the processing steps indicated in 3020 through 3070, depicted in FIG. 19, may be performed at any point following the removal of the carbon cap 1240.

Note that other processes as are commonly used in semiconductor processing may also be included in addition to the embodiments set forth above. For example, gettering processes, passivation processes, planarizing processes, cleaning processes, rinsing processes, drying processes, inspection processes, and the like, as used in semiconductor manufacturing, may be added as necessary. Note that there is no particular limitation to the sequence of steps set forth above.

Note that throughout this disclosure, process segments including removal of a hard mask, patterning of a hard mask, and implantation using the hard mask, as depicted in FIG. 16, may be done in any sequence. For example, the sequence of the processing steps depicted in FIG. 16D may be switched with those depicted in FIG. 16B, with the p channel-forming hard mask 440 formed 1050 and used for aluminum ion implantation 1060 after first the formation of the n channel-forming hard mask 480 and use there to perform the phosphorous ion implantation 1130. That is, there is no particular limitation as to the sequence of the depicted combinations of patterning and implant steps. Hence any descriptions of “first” and “second,” and the like, are used for purely nominal purposes, and have no particular sequential, numerical, or ordinal significance.

The foregoing description of the embodiments of the disclosure has been presented for the purposes of illustration and description. Each and every page of this submission, and all contents thereon, however characterized, identified, or numbered, is considered a substantive part of this application for all purposes, irrespective of form or placement within the application. This specification is not intended to be exhaustive or to limit the disclosure to the precise form disclosed. Many modifications and variations are possible in light of this disclosure.

Note that in this specification and drawings, references to a semiconductor material being “intrinsic” shall be interpreted as including unintentional doping and unavoidable contamination from the environment or introduced during the manufacturing process, in contradistinction to the material having been “doped” deliberately.

Although the present application is shown in a limited number of forms, the scope of the disclosure is not limited to just these forms, but is amenable to various changes and modifications. The present application does not explicitly recite all possible combinations of features that fall within the scope of the disclosure. The features disclosed herein for the various embodiments can generally be interchanged and combined into any combinations that are not self-contradictory without departing from the scope of the disclosure. In particular, the limitations presented in dependent claims below can be combined with their corresponding independent claims in any number and in any order without departing from the scope of this disclosure, unless the dependent claims are logically incompatible with each other.

Various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

All definitions, as defined and used herein, should be understood to control over dictionary definitions, definitions in documents incorporated by reference, and/or ordinary meanings of the defined terms.

The articles “a” and “an,” as used herein in the specification and in the claims, unless clearly indicated to the contrary, should be understood to mean “at least one.” The phrase “and/or,” as used herein in the specification and in the claims (if at all), should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc. As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

While components of the present disclosure are described herein in relation to each other, it is possible for one of the components disclosed herein to include inventive subject matter, if claimed alone or used alone. In keeping with the above example, if the disclosed embodiments teach the features of components A and B, then there may be inventive subject matter in the combination of A and B, A alone, or B alone, unless otherwise stated herein.

Although terms such as “first” and “second” are used herein to describe various features or elements, the features or elements are not be limited by these terms unless the context explicitly indicates otherwise. These terms are used merely to distinguish one feature or element from another. Therefore, a first feature or element described herein could be referred to as a second feature or element, and vice versa, without departing from the teachings of the present invention. Additionally, the presence of a feature or element termed “second” does not necessarily imply the existence of a “first” feature or element in that embodiment or claim. Unless an ordinal relationship is explicitly stated, terms such as “first” and “second” are to be interpreted as mere arbitrary nominal identifiers with no implications regarding sequence or quantity.

An embodiment is an implementation or example of the present disclosure. Reference in the specification to “an embodiment,” “one embodiment,” “some embodiments,” “one particular embodiment,” “an exemplary embodiment,” or “other embodiments,” or the like, means that a particular feature, structure, or characteristic described in connection with the embodiments is included in at least some embodiments, but not necessarily all embodiments, of the invention. The various appearances “an embodiment,” “one embodiment,” “some embodiments,” “one particular embodiment,” “an exemplary embodiment,” or “other embodiments,” or the like, are not necessarily all referring to the same embodiments.

If this specification states a component, feature, structure, or characteristic “may”, “might”, or “could” be included, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

When a feature or element is herein referred to as being “on” another feature or element, it can be directly on the other feature or element or intervening features and/or elements may also be present. In contrast, when a feature or element is referred to as being “directly on” another feature or element, there are no intervening features or elements present.

Additionally, the method of performing the present disclosure may occur in a sequence different than those described herein. Accordingly, no sequence of the method should be read as a limitation unless explicitly stated. It is recognizable that performing some of the steps of the method in a different order could achieve a similar result.

In the foregoing description, certain terms have been used for brevity, clearness, and understanding. No unnecessary limitations are to be implied therefrom beyond the requirement of the prior art because such terms are used for descriptive purposes and are intended to be broadly construed.

Moreover, the description and illustration of various embodiments of the disclosure are examples and the disclosure is not limited to the exact details shown or described.

### EXPLANATIONS OF REFERENCE CODES

100: Photodetector
110: Photodetector Array
120: Photodetector Pixel (Photodetector Structure)
200: Photodiode Portion
202: First Photodiode Portion
204: Second Photodiode Portion
206: First Photosensitive Region
208: Second Photosensitive Region
210: Substrate
220: Epitaxial Layer of Opposite Conductivity Type (Opposite-conductivity-type Low-resistivity Epitaxial Layer)
230: High-Resistivity Epitaxial Layer (Unintentionally-doped Silicon Carbide Epitaxial Layer)
240: Cathode Region (Heavily-doped n-type Cathode Region)
245: Cathode Via
247: Cathode Trace
250: Anode Region (Heavily-doped p-type Anode Region)
255: Segmented Anode
257: Anode Traces
260: Photosensitive Region
270: Ohmic Contact
275: Metal Contact
280: Patterned Metal Interconnection Layer
290: First-frequency UV Bandpass Filter
292: Second-frequency UV Bandpass Filter
300: Junction Field-effect Transistor Portion
301: p-type JFET Portion
302: n-type JFET Portion
305: Processing Portion
310: n Well
320: n⁺ Gate (Heavily-doped First Gate Region)
330: p⁺ Source (First Source/Drain Region, First Source/Drain Subregion)
340: p⁺ Drain (First Source/Drain Region, Second Source/Drain Subregion)
350: p Channel Region (First Channel Region)
351: n Channel Region (Second Channel Region)
360: p Well
370: p⁺ Gate (Second Gate Region)
380: n⁺ Source (Second Source/Drain Region)
390: n⁺ Drain (Second Source/Drain Region)
420: n Well-forming Hard Mask
430: Phosphorous Ions
440: p Channel-forming Hard Mask
450: Aluminum Ions
460: p Well-forming Hard Mask
470: Phosphorous Ions
480: n Channel-forming Hard Mask
490: Phosphorous Ions
500: Anode-forming Hard Mask
510: Aluminum Ions
520: Cathode-forming Hard Mask
530: Phosphorous Ions
600: Thermally Stable Anneal Cap Material
610: Anneal Cap
620: Contact-Forming Hard Mask (Insulating Layer)
630: Deposited Metal
640: Silicide (Ohmic Contact, Silicide Contact)
700: Stack of One or More Dielectric Layers
2230: Epitaxial Layer
2240: Photoresist Layer
2250: Saphire Carrier Substrate
2260: Amorphous SiO₂ Layer
2270: Insulating Substrate
3230: Epitaxial Layer
3240: Photoresist Layer
3250: Saphire Carrier Substrate
3260: Via (Metal Via)
3270: Ground Plane
3280: Insulating Substrate
3290: Thin Metal Layer (Metal Layer)

What is claimed is:

1. A photodetector, comprising:
at least one photodetector structure, disposed on a substrate, said photodetector structure comprising:
an unintentionally-doped silicon carbide high-resistivity epitaxial layer disposed over the substrate;
at least one heavily-doped n-type cathode region formed in the high-resistivity epitaxial layer;
at least one heavily-doped p-type anode region formed in the high-resistivity epitaxial layer;
at least one photosensitive region, of the high-resistivity epitaxial layer, interposed between the anode region and the cathode region in the high-resistivity epitaxial layer;
an insulating layer formed over at least a portion of the substrate, with windows to allow access to the cathode region and to the anode region, and configured to enable UV radiation to be incident onto the photosensitive region; and
silicide contacts in contact with the cathode region and the anode region; wherein
the anode region, the cathode region, and the photosensitive region are formed in the high-resistivity epitaxial layer in a lateral configuration.

2. The photodetector of claim 1, wherein:
the substrate is a SiC epi-compatible material.

3. The photodetector of claim 2, wherein:
the substrate is a SiC 4H or 6H substrate of one conductivity type having an opposite-conductivity-type low-resistivity epitaxial layer formed on a surface thereof.

4. The photodetector of claim 1, wherein:
the substrate is an insulating substrate having a SiO₂ layer on a surface thereof.

5. The photodetector of claim 1, wherein:
the substrate is an insulating substrate having a metal layer on a surface thereof; and
metal vias pass through the high-resistivity epitaxial layer and connect with the metal layer.

6. The photodetector of claim 1, further comprising:
at least one optical filter, provided over at least one said photosensitive region.

7. The photodetector of claim 1, further comprising
at least one first junction field-effect transistor, comprising:
a lightly-doped first channel region, of a first conductivity type, formed in the high-resistivity epitaxial layer;
a heavily-doped first gate region, of a second conductivity type that is the opposite conductivity type from the first conductivity type, formed at least partially in the channel region; and
heavily-doped first source/drain regions, of the first conductivity type, formed at least partially in the channel region, wherein:
the insulating layer has windows opened to allow access also to the first gate region and the first source/drain regions; and
silicide contacts contact also the first gate region and the first source/drain regions.

8. The photodetector of claim 7, wherein:
the first source/drain regions comprise at least one first source/drain subregion and at least one second source/drain subregion, arranged opposing each other; and
the first gate region comprises a plurality of first gate regions, arranged in a row between the first source/drain subregion and the second source/drain subregion.

9. The photodetector of claim 8, wherein:
the first source/drain subregion comprises a plurality of first source/drain subregions, arranged in a row parallel to a row of the first gate regions, such that each of the first source/drain subregions faces an aforementioned second source/drain subregion through a space between mutually adjacent first gate regions.

10. The photodetector of claim 7, wherein:
the first gate region comprises a plurality of first gate regions, arranged in two rows, with each individual first gate region in one row paired with and facing a corresponding first gate region in the other row; and
the first source/drain regions are arranged in a row, parallel to the rows of first gate regions, facing each other through spaces between pairs of first gate regions.

11. The photodetector of claim 7, further comprising:
a lightly-doped well, of the second conductivity type, containing the first channel region, the first gate region, and the first source/drain regions.

12. The photodetector of claim 7, further comprising: an amplifier, comprising a plurality of the junction field-effect transistor, electrically coupled to the p-type anode region and the n-type cathode region through a patterned metal interconnection layer.

13. The photodetector of claim 7, further comprising
at least one second junction field-effect transistor, comprising:
a lightly-doped second channel region, of the second conductivity type, formed in the high-resistivity epitaxial layer;
a heavily-doped second gate region, of the first conductivity type, formed at least partially in the channel region of the second conductivity type; and
heavily-doped second source/drain regions, of the second conductivity type, formed at least partially in the channel region of the second conductivity type.

14. The photodetector of claim 7, wherein:
the at least one photodetector structure comprises a plurality of photodetector structures; and
the at least one first junction field-effect transistor comprises a plurality of first junction field-effect transistors, wherein
a plurality of pixel photodetector structures is arranged in a matrix, where each of the plurality of pixel photodetector structures comprises at least one of said photodetector structures and at least one of said first junction field-effect transistors.

15. The photodetector of claim 5, wherein:
the at least one photodetector structure comprises a plurality of photodetector structures, arranged in a matrix; and
at least one cathode or at least one anode is connected to the metal layer through at least one of the metal vias.

16. A method for manufacturing a photodetector, comprising:
growing a high-resistivity epitaxial layer over a substrate of a SiC epi-compatible material;
forming an anode-forming hard mask layer over the high-resistivity epitaxial layer and patterning the anode-forming hard mask layer to form a window over an area for heavy ion implantation of a p-type dopant for forming an anode of a photodiode;
performing heavy heated ion implantation of the p-type dopant and removing the anode-forming hard mask layer;
forming a cathode-forming hard mask layer over the high-resistivity epitaxial layer and patterning the cathode-forming hard mask layer to form a window over an area for heavy ion implantation of an n-type dopant for forming a cathode of the photodiode;
performing heavy heated ion implantation of the n-type dopant; and removing the cathode-forming hard mask layer;
cleaning the surface of the substrate; depositing an anneal cap of a thermally stable material to prevent step-bunching, annealing the anneal cap, and removing the anneal cap; and
forming a contact-forming hard mask layer over the high-resistivity epitaxial layer, patterning the contact-forming hard mask layer to form a window over a contact-forming area of a region into which ions have been implanted, depositing a film of a metal for forming an ohmic contact layer, annealing,
silicidizing the ohmic contact layer, and
removing any residual unreacted metal.

17. The method of claim 16, further comprising:
forming a p channel for a junction field-effect transistor, comprising:
forming a p channel-forming hard mask layer over the high-resistivity epitaxial layer; patterning the p channel-forming hard mask layer to form windows over areas for light ion implantation of a p-type dopant;
performing light heated ion implantation of the p-type dopant, and removing the p channel-forming hard mask layer; and
forming an n channel for a junction field-effect transistor, comprising: forming a n channel-forming hard mask layer over the high-resistivity epitaxial layer; patterning the n channel-forming hard mask layer to form windows over areas for light ion implantation of the n-type dopant; performing light heated ion implantation of the n-type dopant;
and removing the n channel-forming hard mask layer; wherein patterning the anode-forming hard mask layer comprises forming windows also over areas for forming a p+ gate of an n-type junction field-effect transistor and a p+ source and a p+ drain of a p-type junction field-effect transistor, in addition to the window for forming the anode of the photodiode; and
patterning the cathode-forming hard mask layer comprises forming windows over areas for forming an n+ gate of the p-type junction field-effect transistor and an n+ source and an n+ drain of the n-type junction field-effect transistor, in addition to forming the cathode of the photodiode.

18. The method of claim 16, further comprising:
growing, over the substrate, a low-resistivity silicon carbide epitaxial layer of the conductivity type that is opposite of the conductivity type of the substrate, prior to growing the high-resistivity epitaxial layer.

19. The method of claim 16, further comprising:
forming an optical filter.

20. The method of claim 16, further comprising:
bonding a high-resistivity epitaxial layer to a carrier substrate through a photoresist layer;
removing the substrate of the SiC epi-compatible material;
after removing the substrate of the SiC epi-compatible material, depositing a SiO₂ layer onto the high-resistivity epitaxial layer;
bonding the SiO₂ layer onto an insulating substrate; and
removing the carrier substrate.

21. The method of claim 16, further comprising:
bonding the high-resistivity epitaxial layer to a carrier substrate through a photoresist layer;
removing the substrate of the SiC epi-compatible material;
forming vias through the high-resistivity epitaxial layer;
metalizing the vias and forming a metal layer on the epitaxial layer; and
bonding the metal layer onto a metal layer that is on an insulating substrate.
